(19) United States
(12) Patent Application Publication
(10) Pub. No.: US 2026/0068245 A1
(43) Pub. Date: Mar. 5, 2026

(54) NANOSTRUCTURE FIELD-EFFECT TRANSISTOR DEVICE WITH SHALLOW-TRENCH ISOLATION PROTECTION STRUCTURE AND METHODS OF FORMING

(71) Applicant: Taiwan Semiconductor Manufacturing Co., Ltd., Hsinchu (TW)

(72) Inventors: Ting-Hsiang Chang, New Taipei City (TW); Chung-Ting Ko, Kaohsiung City (TW); Tai-Jung Kuo, Hsinchu (TW); Sung-En Lin, Xionglin Township (TW); Tai-Chun Huang, Hsinchu (TW)

(21) Appl. No.: 18/890,059

(22) Filed: Sep. 19, 2024

Related U.S. Application Data
(60) Provisional application No. 63/690,390, filed on Sep. 4, 2024.

(51) Int. Cl. H01L 29/06; H01L 29/423; H01L 29/66

(52) U.S. Cl. CPC H10D 62/121; H10D 30/014; H10D 30/6735; H10D 64/017

(57) ABSTRACT

Various examples related to a shallow trench isolation (STI) protection structure formed on the STI regions of a nanostructure field-effect transistor (NSFET) device are disclosed. The STI protection structure protects the STI regions (e.g., portions directly under dummy gate structures) during a subsequent selective etching process. The STI protection structures includes a liner layer and a hard mask layer(s) formed on the liner layer. In a first set of examples, the hard mask layer(s) on the liner layer are manipulated by various processing steps to achieve different profiles (e.g., concave, convex, or flat) for the upper surfaces of the STI protection structure. A second set of examples are disclosed for enhancing the quality of the liner layer of the STI protection structure through different plasma processes, such that the liner layer is more resistant to the subsequent etching process.

### PRIORITY CLAIM AND CROSS-REFERENCE

This application claims priority to U.S. Provisional Application No. 63/690,390, filed Sep. 4, 2024 and entitled “Method For Forming A Semiconductor Structure,” which application is incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 24A, 24B, 25A, and 25B are cross-sectional views of a portion of a nanostructure field-effect transistor (NSFET) device at various stages of manufacturing, in accordance with an embodiment.

FIGS. 26A, 26B, 27A, 27B, 28A, and 28B are cross-sectional views of a portion of a nanostructure field-effect transistor (NSFET) device at various stages of manufacturing, in accordance with another embodiment.

FIGS. 29A, 29B, 30A, and 30B are cross-sectional views of a portion of a nanostructure field-effect transistor (NSFET) device at various stages of manufacturing, in accordance with yet another embodiment.

FIGS. 31A and 31B together illustrate a flow chart of a method of forming a semiconductor device, in some embodiments.

FIGS. 32A 32B, 33A, 33B, 34A, 34B, 35A, 35B, 36A, 36B, 36C, 37A, 37B, 38A, 38B, 39A, and 39B are cross-sectional views of a portion of a nanostructure field-effect transistor (NSFET) device at various stages of manufacturing, in accordance with an embodiment.

FIGS. 40A and 40B are cross-sectional views of a portion of a nanostructure field-effect transistor (NSFET) device, in accordance with another embodiment.

FIGS. 41A and 41B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

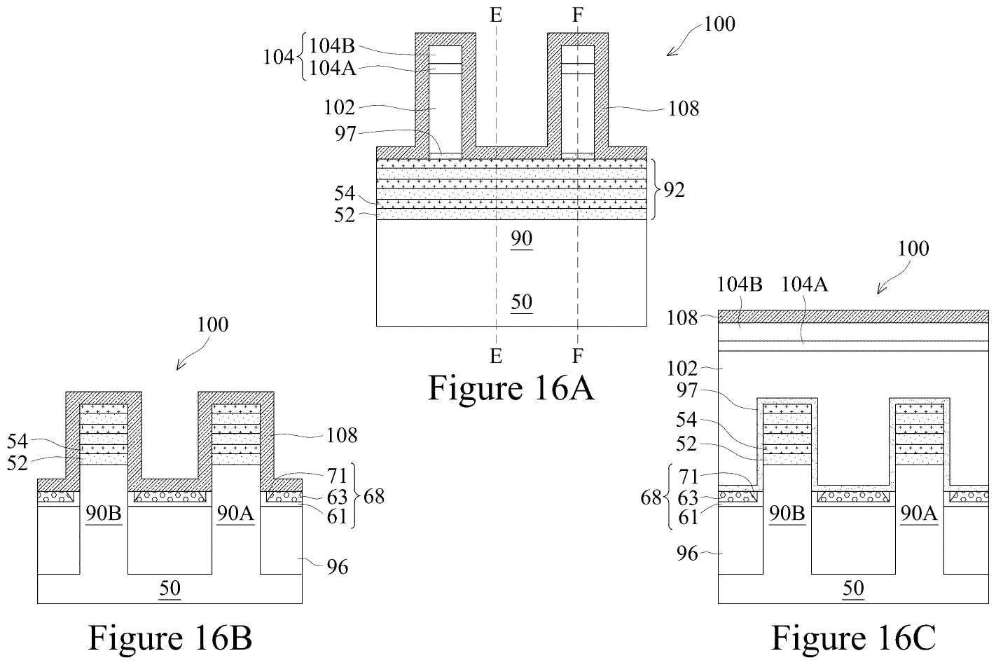

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 16A-16C) illustrate different views of the same device at the same stage of processing.

Disclosed embodiments relate to a shallow trench isolation (STI) protection structure formed on the STI regions of an NSFET device. The STI protection structure protects the STI regions (e.g., portions directly under dummy gate structures) during the selective etching of a disposable material used in a disposable oxide interposer (DOI) process for forming NSFET devices. The STI protection structures includes a liner layer and a hard mask layer(s) formed on the liner layer. A first set of embodiments are disclosed for forming the STI protection structure with concave, convex, or flat upper surfaces. In the first set of embodiments, the hard mask layer(s) on the liner layer are manipulated by various processing steps to achieve different profiles (e.g., concave, convex, or flat) for the upper surfaces of the STI protection structure. A second set of embodiments are disclosed for enhancing the quality of the liner layer of the STI protection structure through different plasma processes, such that the liner layer is more resistant to the subsequent etching process(es).

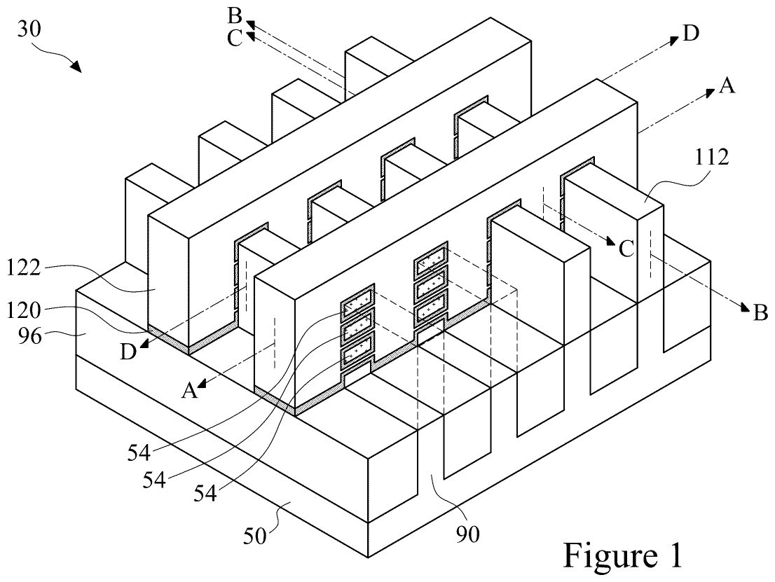

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

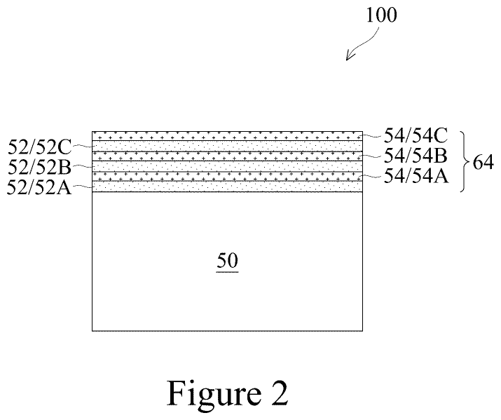

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 24A, 24B, 25A, and 25B are cross-sectional views of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

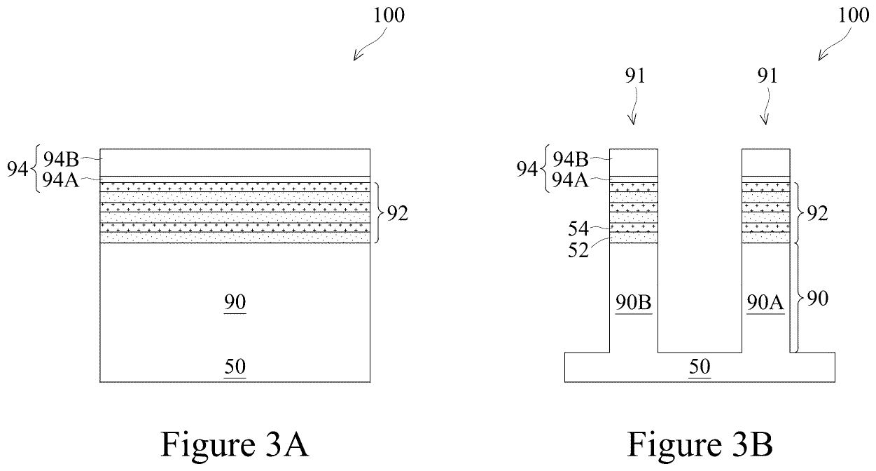

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, 16B, 16C, 17A, 17B, 17C, 18A, 18B, 18C, 19A, 19B, 19C, 20A, 20B, 20C, 21A, 21B, 21C, 22A, 22B, 22C, 23A, 23B, 24A, 24B, 25A, and 25B are cross-sectional views of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, and 25A are cross-sectional views along cross-section B-B in FIG. 1. FIGS. 3B, 4B, 5B, 6B, 7B, 8B, 9B, 10B, 11B, 12B, 13B, 14B, 15B, 16C, 17C, 18C, 19C, 20C, 21C, 22C, 23B, 24B, and 25B are cross-sectional views along cross-section A-A in FIG. 1. FIGS. 16B, 17B, 18B, 19B, 20B, 21B, and 22B are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A or 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

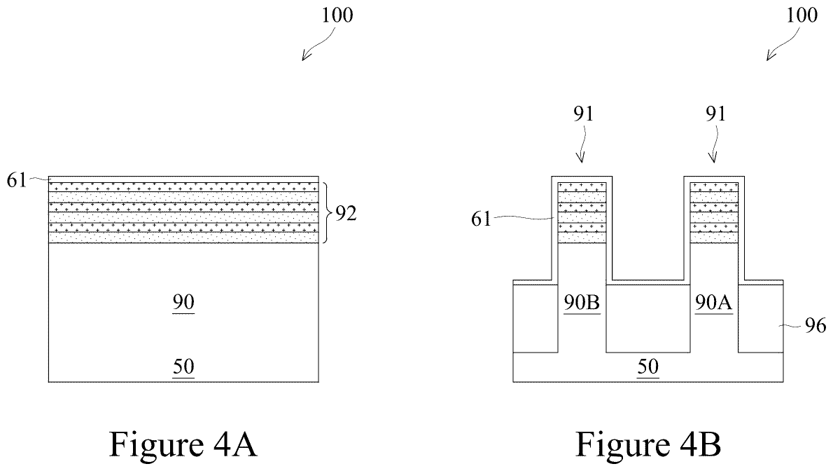

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner (not shown) is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a liner layer 61 is formed over the layer stacks 92 and over the STI regions 96. The liner layer 61 may be a suitable dielectric material such as silicon oxide, and may be formed using a suitable deposition method such as CVD, atomic layer deposition (ALD), or the like. The liner layer 61 protects the layer stacks 92 from damage by subsequent etching process(es) used to form an STI protection structure 68, in some embodiments. The liner layer 61 may also be referred to as an oxide liner layer. Besides silicon oxide, other suitable material, such as a dielectric material that provides high etching selectivity from the layer stack 92 and the subsequently formed hard mask layer (e.g., 63, 65, 71) may also be used. In the illustrated embodiments, the liner layer 61 is a conformal layer that has a substantially uniform thickness.

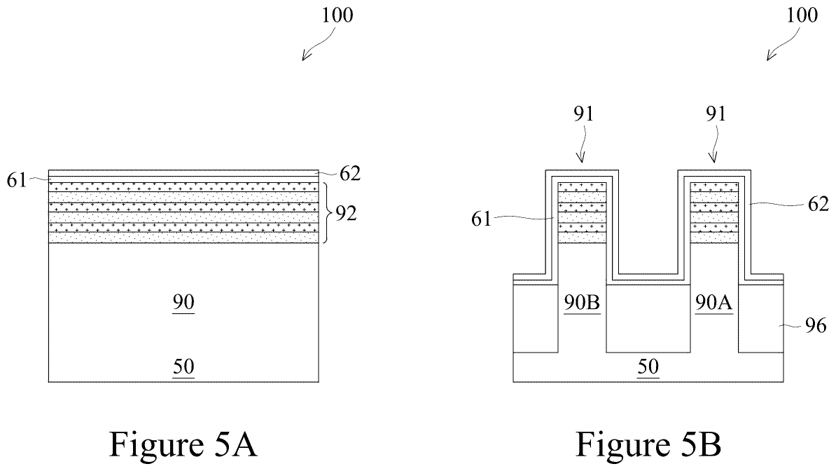

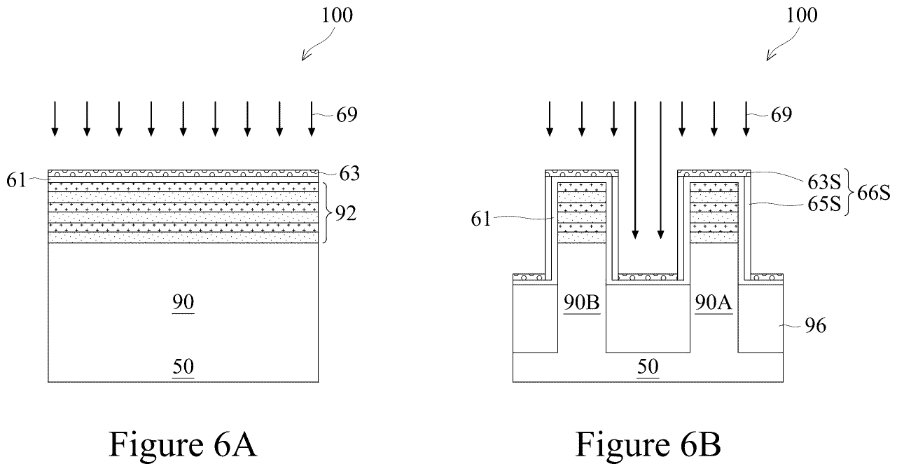

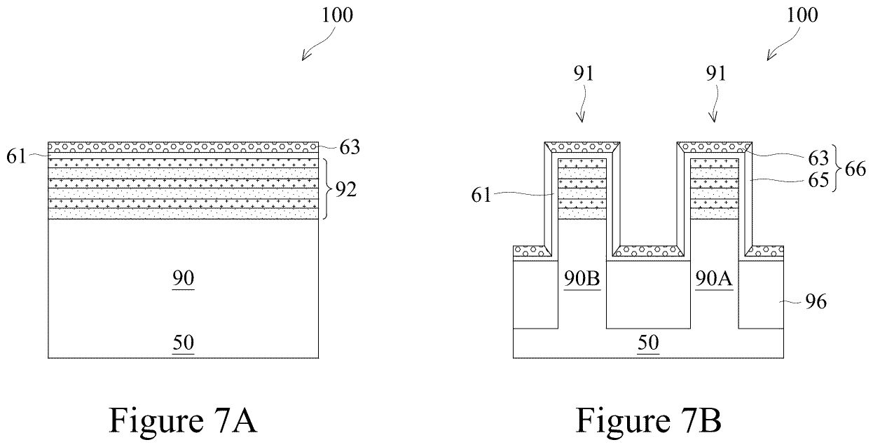

Next, a hard mask layer 66 (see, e.g., FIG. 7B) is formed on the liner layer 61. The hard mask layer 66 is formed by a suitable deposition process, such as an ALD process, a conformal CVD process, or the like. In some embodiments, the hard mask layer 66 is formed by a deposition process (e.g., a plasma-enhanced ALD (PEALD) process) that includes a plurality of deposition cycles, where each of the plurality of deposition cycles forms a sublayer 66S of the hard mask layer 66. FIGS. 5A, 5B, 6A, and 6B illustrate the processing steps of a deposition cycle for forming a sublayer 66S of the hard mask layer 66. FIGS. 7A and 7B illustrate the hard mask layer 66 after the deposition process (e.g., PEALD process) is completed.

The hard mask layer 66 is formed of a material different from the liner layer 61 and the STI regions 96. In some embodiments, the material of the hard mask layer 66 is chosen to provide high etching selectivity from the material of the STI regions 96, such that in a subsequent sheet formation process (e.g., an etching process) to form nanostructures (e.g., nanosheets), the hard mask layer 66 protects the STI regions 96 to prevent loss of the STI regions 96. In an embodiment, the STI regions 96 comprises silicon oxide, and the hard mask layer 66 comprises silicon nitride. Besides silicon nitride, other suitable materials, such as silicon oxynitride, silicon carbonitride, or the like, may also be used for the hard mask layer 66.

In some embodiments, the hard mask layer 66 is formed by a PEALD process disclosed herein. The PEALD process includes multiple deposition cycles, where each deposition cycle includes a plurality of processing steps performed sequentially in a process chamber. In some embodiments, the plurality of processing steps in a deposition cycle includes a first processing step and a second processing step performed sequentially. After each of the first and the second processing steps, the un-used precursors, the plasma generated during the processing step, and/or the byproduct(s) of the processing step (if any), are evacuated (e.g., purged, or pumped out) from the process chamber. For ease of discussion, the layer of material formed after the completion of each deposition cycle of the PEALD process is referred to as a sublayer 66S of the hard mask layer 66.

FIGS. 5A and 5B illustrate the first processing step in a deposition cycle. In the illustrated embodiment, the first processing step forms a first layer of material 62 on the underlying layer (e.g., the liner layer 61, or a previously formed sublayer 66S of the hard mask layer 66). In an embodiment, a silicon-containing precursor, such as dichlorosilane (SiH₂Cl₂), is supplied to the process chamber and adsorbs on the surface of underlying layer, thus forming the first layer of material 62 (e.g., a layer of chemically bound precursor molecules, which may also be referred to as an adsorbed precursor layer). After the first processing step, un-used precursor and/or byproduct(s) (if any) are evacuated from the process chamber.

FIGS. 6A and 6B illustrate the second processing step in the deposition cycle. In the second processing step of the deposition cycle, an anisotropic plasma process 69 is performed to treat the first layer of material 62 and turn the first layer of material 62 into a second layer of material 66S (e.g., a sublayer 66S). In an embodiment, the anisotropic plasma process 69 is performed using a gas source comprising nitrogen gas (N₂). The gas source is ignited into a plasma by an RF power source, and the N₂ plasma reacts with the first layer of material 62 and turns the first layer of material 62 into the second layer of material 66S. The chemical reaction between the first layer of material 62 (which comprises SiH₂Cl₂ and/or SiHₓCl_{y} species) and the nitrogen plasma produces silicon nitride (e.g., SiN) and volatile byproduct (e.g., HCl). After the second processing step is finished, un-used gas source, plasma, and/or byproduct(s) (if any) are evacuated from the process chamber.

Due to the anisotropicity of the anisotropic plasma process 69, horizontal portions of the first layer of material 62 (e.g., portions disposed along the top surfaces of the fin structures 91 and along the upper surfaces of the STI regions 96) are subject to more nitrogen plasma than the vertical portions of the first layer of material 62 (e.g., portions disposed along the sidewalls of the fin structures 91). As a result, the second layer of material 66S is formed to have horizontal portions 63S and vertical portions 65S that have different material compositions and/or physical properties. The horizontal portions 63S are disposed along the top surfaces of the fin structures 91 and along the upper surfaces of the STI regions 96, and the vertical portions 65S are disposed along the sidewalls of the fin structures 91. The material composition of the horizontal portions 63S has a higher percentage of silicon nitride than that of the vertical portions 65S. For example, all or most the SiH₂Cl₂ and/or SiHₓCl_{y} species in the horizontal portions of the first layer of material 62 are nitridized and converted into silicon nitride, whereas a smaller percentage of the SiH₂Cl₂ and/or SiHₓCl_{y} species in the vertical portions of the first layer of material 62 are nitridized and converted into silicon nitride. As a result, the horizontal portions 63S comprise mostly silicon nitride, with a smaller percentage or no SiH₂Cl₂ or SiHₓCl_{y} species, and the vertical portions 65S comprise a smaller percentage of silicon nitride but a higher percentage of SiH₂Cl₂ or SiHₓCl_{y} species than the horizontal portions 63S, in some embodiments. In addition, the horizontal portions 63S have a higher density than the vertical portions 65S, and have a slower etch rate (e.g., is more etch resistant) than the vertical portions 65 in a subsequent etching process performed for removing the sidewall portions of the hard mask layer 66. The above described deposition cycle is repeated to form multiple sublayers 66S successively on the liner layer 61 to form the hard mask layer 66. The PEALD process is stopped when the thickness of the hard mask layer 66 reaches a target value.

FIGS. 7A and 7B illustrate the hard mask layer 66 after the PEALD process is completed. Similar to FIGS. 6A and 6B, the hard mask layer 66 includes horizontal portions 63 and vertical portions 65, which are formed by the horizontal portions 63S and vertical portions 65S of all of the sublayers 66S, respectively. For ease of discussion, the horizontal portions 63 disposed along the top surfaces of the fin structures 91 may also be referred to as top portions 63, the horizontal portions 63 disposed along the upper surfaces of the STI regions 96 may also be referred to as bottom portions 63, and the vertical portions 65 may also be referred to as sidewall portions 65. The material compositions and/or physical properties of the horizontal portions 63 and the vertical portions 65 are the same as or similar to those of the horizontal portions 63S and the vertical portions 65S, respectively, thus details are not repeated.

Note that in the above example, silicon nitride is used as a non-limiting example of the material of the hard mask layer 66. Other suitable material, such as silicon oxynitride, silicon carbonitride, or the like, may also be used for the hard mask layer 66, and the deposition method disclosed above (e.g., the PEALD process) may be adapted to form the different materials for the hard mask layer 66, as skilled artisans readily appreciate. In an embodiment, in the first processing step of the deposition cycle, a layer of silicon oxide (e.g., SiO) is formed. Various methods for forming the layer of silicon oxide in the first processing step are possible. For example, a precursor that already contains Si—O bonds, such as tetraethoxysilane (TEOS) may be used in the first processing step. The precursor may decompose to form SiO-like species on the surface of the underlying layer (e.g., the liner layer 61, or a previously formed sublayer 66S). As another example, in the first processing step, a silicon-containing precursor, such as silane (SiH₄) or dichlorosilane (SiH₂Cl₂), may be used in conjunction with an oxygen plasma or oxygen-containing plasma. The plasma energy could help break down the precursor and form Si—O bonds. Then, in the second processing step, the N₂ plasma converts the silicon oxide into silicon oxynitride. In another embodiment, the first processing step forms a layer of silicon carbide, and the N₂ plasma in the second processing step converts the silicon carbide into silicon carbonitride.

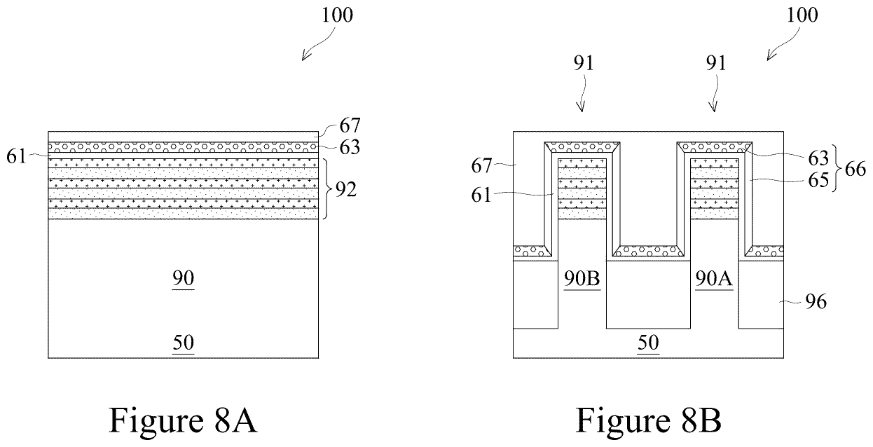

Next, in FIGS. 8A and 8B, a mask layer 67 is formed over the hard mask layer 66. In some embodiments, the mask layer 67 is a Bottom Anti-Reflective Coating (BARC) layer typically used in a tri-layered photoresist. The BARC layer may be a carbon-containing material, such as spin-on glass (SOG) carbon, as an example. Therefore, the mask layer 67 may also be referred to as a BARC layer 67 in the discussion herein, with the understanding that other suitable materials may also be used. As illustrated in FIGS. 8A and 8B, the BARC layer 67 fills the trenches between adjacent fin structures 91, and covers the top surfaces of the fin structures 91.

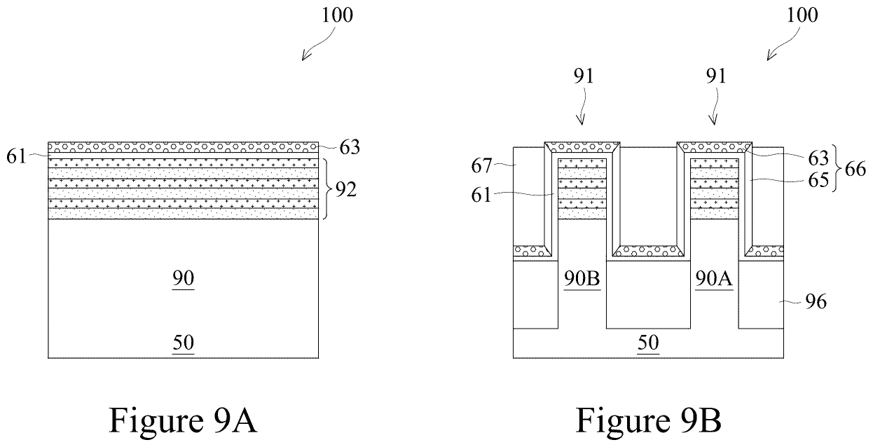

Next, in FIGS. 9A and 9B, the BARC layer 67 is etched back to expose the top portions 63 of the hard mask layer 66. A suitable etching process, such as a dry etching process, a wet etching process, combinations thereof, or the like, may be performed to etch back the BARC layer 67. The etching process may be a timed process to etch back the BARC layer 67 by a pre-determined amount. In some embodiments, the etching process is performed using an etchant selective to (e.g., having a higher etch rate for) the material of the BARC layer 67, such that the BARC layer 67 is removed without substantially attacking the hard mask layer 66.

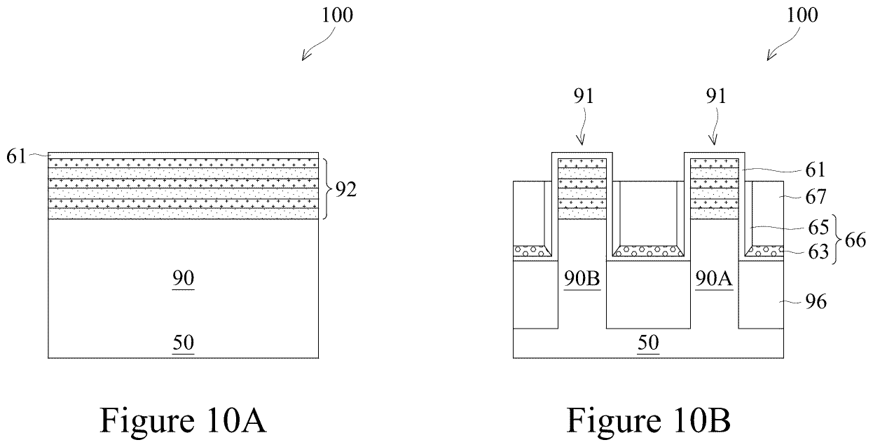

Next, in FIGS. 10A and 10B, the exposed top portions 63 of the hard mask layer 66 are removed by an etching process. For example, a dry etching process using, e.g., a gas source comprising a fluorine-based etching gas, may be performed to remove the exposed top portions 63 of the hard mask layer 66. The gas source may include NF₃ and H₂, as an example. As another example, a wet etching process using, e.g., phosphoric acid (H₃PO₄), may be performed to remove the exposed top portions 63 of the hard mask layer 66. In the illustrated example of FIGS. 10A and 10B, the etching process also recesses the BARC layer 67 and removes upper portions of the sidewall portions 65 of the hard mask layer 66. Due to the etching selectivity between the liner layer 61 and the BARC layer 67/the hard mask layer 66, the liner layer 61 remains substantially un-etched, and covers the sidewalls of the fin structures 91 and the top surfaces of the fin structures 91. Therefore, the liner layer 61 protects the layer stacks 92 (and subsequently formed nanostructures 54) from damage caused by the etching processes used for forming the STI protection structure 68.

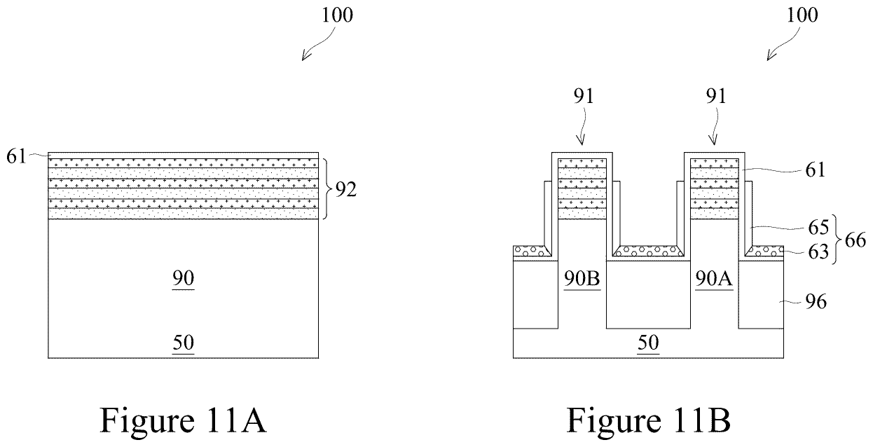

Next, in FIGS. 11A and 11B, the remaining portions of the BARC layer 67 are removed by an etching process. The etching process may be dry etching, wet etching, combinations thereof, or the like. In some embodiments, the etching process is a plasma etching process performed using a gas source comprising H₂ and N₂ gases. After the removal of the remaining portions of the BARC layer 67, remaining portions of the hard mask layer 66 are exposed. The remaining portions of the hard mask layer 73 include sidewall portions 65 along the sidewalls of the fin structures 91, and include bottom portions 63 along the upper surfaces of the STI region 96.

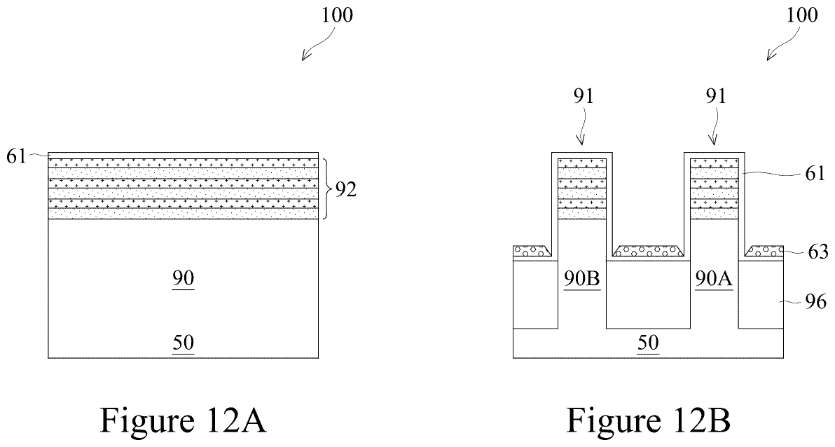

Next, in FIGS. 12A and 12B, the sidewall portions 65 of the hard mask layer 66 are removed by an etching process (e.g., an isotropic etching process). The etching process may be a dry etching process, a wet etching process, combinations thereof, or the like. In some embodiments, a dry etching process is performed to remove the sidewall portions 65 of the hard mask layer 66 using a fluorine-based etching gas, such as HF, NF₃, or combinations thereof. In some embodiments, a wet etching process is performed to remove the sidewall portions 65 of the hard mask layer 66. In an embodiment, the wet etching process is performed by etching using a first etchant (e.g., H₃PO₄) for a first duration of time, then etching using a second etchant (e.g., SC1, which is a mixture of deionized water, ammonia water, and hydrogen peroxide) for a second duration of time.

Recall that sidewalls portions 65 of the hard mask layer 66 have a faster etch rate (e.g., due to its lower density and/or less percentage of silicon nitride) than the bottom portions 63 of the hard mask layer 66. Therefore, the sidewall portions 65 are removed (e.g., completely remove) from the sidewalls of the fin structure 91 by the etching process (e.g., an isotropic etching process), while the bottom portions 63 remain and cover the upper surfaces of the STI regions 96, although with reduced thickness due to the etching process. As illustrated in FIGS. 12A and 12B, the remaining bottom portions 63 have convex upper surfaces. The remaining bottom portions 63 form part of the subsequently formed STI protection structure 68. For ease of discussion, the remaining bottom portions 63 may also be referred to as a hard mask layer 63 hereinafter.

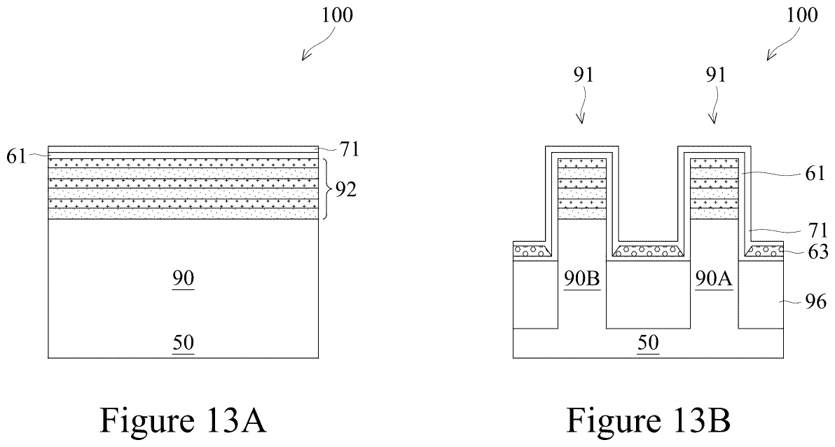

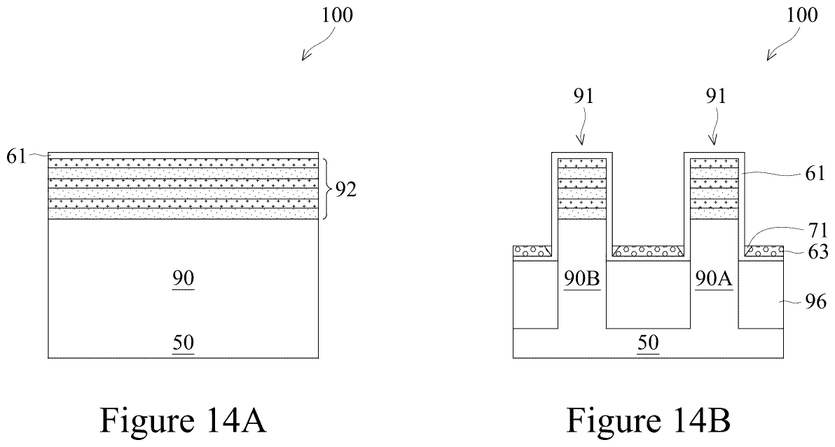

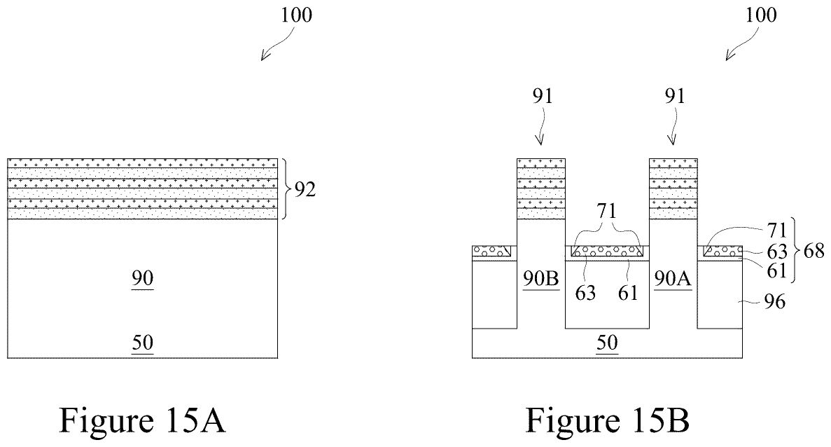

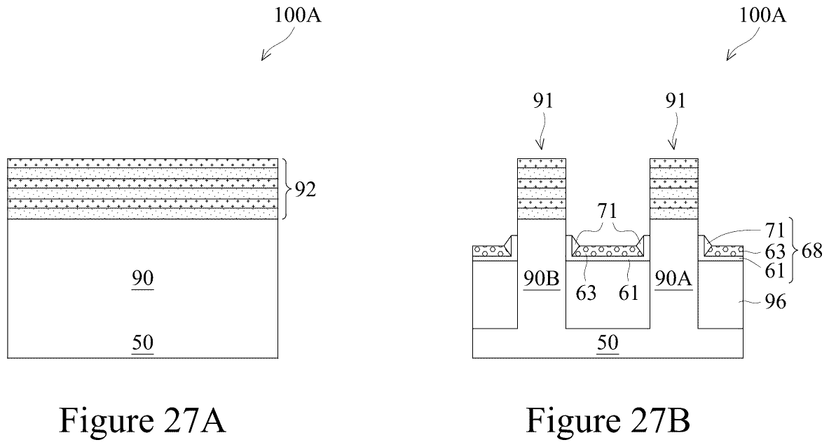

Next, in FIGS. 13A and 13B, a hard mask layer 71 is formed (e.g., conformally) on the liner layer 61 and the hard mask layer 63. The hard mask layer 71 fills empty spaces between the hard mask layer 63 and the liner layer 61 at corner regions where the upper surfaces of the STI regions 96 intersect the sidewalls of the fins 90. The hard mask layer 71 may be formed by a suitable deposition method, such as an ALD process or a conformal CVD process. In some embodiments, the hard mask layer 71 is a dielectric material chosen based on its etch rate relative to the etch rate of the hard mask layer 63, in order to achieve a target profile (e.g., concave upper surfaces, or flat upper surfaces) for the STI protection structure 68 formed subsequently. In the example of FIGS. 13A-15B, the hard mask layer 71 has a density that is the same as or slightly lower (e.g., less than 10% lower) than the hard mask layer 63. In addition, or alternatively, the hard mask layer 71 has a same etch rate as, or a slightly slower etch rate (e.g., less than 10% slower) than, the hard mask layer 63 for the subsequent etching process of FIGS. 14A and 14B, and as a result, the subsequently formed STI protection structure 68 has flat upper surfaces (see, e.g., FIG. 15B). In another embodiment, the hard mask layer 71 has a higher density than the hard mask layer 63, and/or has a slower etch rate than the hard mask layer 63 for the subsequent etching process of FIGS. 14A and 14B, and as a result, the subsequently formed STI protection structure 68 has concave upper surfaces (see, e.g., FIG. 27B).

In some embodiments, the hard mask layer 63 may be or comprise a material selected from the group consisting of silicon nitride, silicon oxynitride, and silicon carbonitride, and the hard mask layer 71 may be or comprise a material selected from the group consisting of silicon nitride and silicon oxide. The hard mask layer 63 and the hard mask layer 71 may comprise different materials (e.g., one comprising silicon oxynitride, the other one comprising silicon nitride) to achieve different etch rates, as an example. As another example, the hard mask layer 63 and the hard mask layer 71 may comprise the same material (e.g., silicon nitride), but have different densities and etch rates. For instance, the hard mask layer 71 may be a silicon nitride layer formed using a CVD deposition process, and the hard mask layer 63 may be a silicon nitride layer formed using a PEALD deposition process, and the CVD deposition process may produce silicon nitride with higher density than that formed by the PEALD deposition process.

Next, in FIGS. 14A and 14B, an etching process is performed to remove the hard mask layer 71 from the top surfaces of the layer stacks 92, the sidewalls of the layer stack 92, and upper surfaces of the hard mask layer 63. A suitable etching process, such as dry etching, wet etching, combinations thereof, or the like, may be performed. In an embodiment, the etching process is a wet etching process performed using a fluorine-based etchant, such as HF. After the etching process, portions of the hard mask layer 71 remain at the corner regions where the upper surfaces of the STI regions 96 intersect the sidewalls of the fins 90. For example, remaining portions of the hard mask layer 71 are disposed laterally between the liner layer 61 and the hard mask layer 63. In the example of FIGS. 14A and 14B, the upper surface of the remaining portions of the hard mask layer 71 is level with the upper surface of the hard mask layer 63.

Next, in FIGS. 15A and 15B, portions of the liner layer 61 disposed above the hard mask layer 63 and the remaining portions of the hard mask layer 71 are removed by an etching process. A suitable etching process, such as dry etching process, wet etching process, combinations thereof, or the like, may be used to remove the portions of the liner layer 61. In an embodiment, the portions of the liner layer 61 is removed by a wet etching process performed using a mixture of HF and SC1. After the etching process, the remaining portions of the liner layer 61, the hard mask layer 63, and the remaining portions of the hard mask layer 71 form the STI protection structure 68. As illustrated in FIGS. 15A and 15B, the STI protection structure 68 covers (e.g., contacts and extends along) the upper surfaces of the STI regions 96. The STI protection structure 68 protects (e.g., shields) the STI regions 96 in the subsequent sheet formation process to prevent or reduce loss of the STI regions 96 disposed directly under the dummy gate structure.

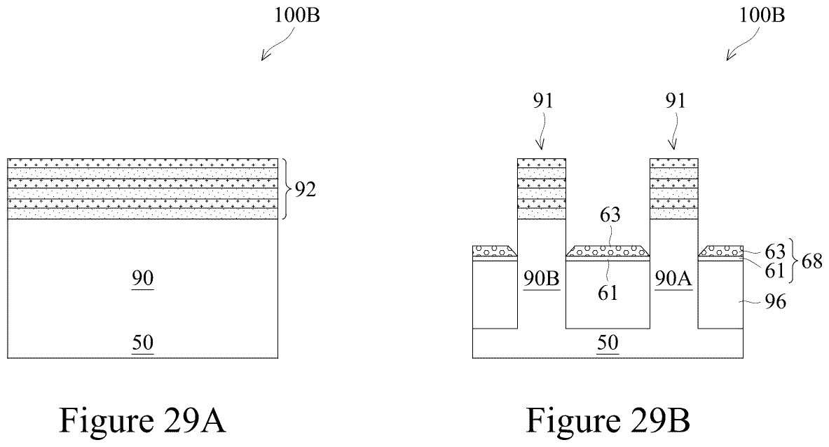

In FIG. 15B, the liner layer 61 of the STI protection structure 68 extends along the sidewalls of the remaining portions of the hard mask layer 71, and along the bottom surface of the hard mask layer 63. In the example of FIG. 15B, the STI protection structure 68 has flat upper surfaces distal from the substrate 50. In some embodiments, the STI protection structure 68 has concave upper surfaces distal from the substrate 50, as illustrated in FIG. 27B and discussed hereinafter. In some embodiments, the STI protection structure 68 has convex upper surfaces, as illustrated in FIG. 29B and discussed hereinafter. These and other variations are fully intended to be included within the scope of the present disclosure.

In advanced semiconductor manufacturing process, the aspect ratio of the trenches between adjacent fin structures 91 increases significantly, and it is becoming increasingly challenging for etching processes to reach the bottoms of these trenches. Therefore, it is difficult to control the profile of the structures (e.g., the STI protection structure) disposed at the bottoms of the trenches using etching processes alone. The present disclosure allows for precise control of the profile (e.g., shape of the upper surfaces) of the STI protection structure 68, which provides advantages for manufacturing. For example, the materials (e.g., 61, 63, 71) of the STI protection structure 68 are subject to various etching processes, such as the subsequent etching process for removing the dummy gate structure. The etching process(es) may etch (e.g., remove) the materials of the STI protection structure 68 in different ways. For example, some dry etching processes (e.g., plasma etching) tend to remove materials at the center regions of the trenches at a faster rate, and some wet etching processes tend to remove materials at the corner regions of the trenches at a faster rate. To compensate for the extra etching at the center regions and to prevent the STI protection structure 68 from being etched through in the center regions, convex upper surfaces for the STI protection structure 68 may be advantageous, because the center regions of the STI protection structure 68 are thicker. Conversely, to compensate for extra etching at the corner regions, concave upper surfaces for the STI protection structure 68 may be advantageous, because the corner regions of the STI protection structure 68 are thicker. Without the presently disclosed methods, the STI protection structure 68 may be damaged (e.g., etched through) by the etching process(es) and may fail to protect the underlying structures (e.g., fins, STI regions) from the etching process(es), thus causing device failure. The current disclosure provides the ability to control the profile of the STI protection structure 68, thus preventing the STI protection structure 68 from being damaged (e.g., etched through) by subsequent etching process(es) and improving production yield.

Next, in FIGS. 16A-16C, a dummy dielectric layer 97 is formed over the STI protection structure 68 and over the sidewalls and the top surfaces of the fin structure 91. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI protection structure 68, and a thermal oxidization process is performed to convert the deposited silicon layer into an oxide layer as the dummy dielectric layer 97.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure.

Next, a gate spacer layer 108 is formed by conformally depositing an insulating material over the layer stacks 92, the STI protection structure 68, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 16B and 16C illustrate cross-sectional views of the NSFET device 100 in FIG. 16A along cross-sections E-E and F-F in FIG. 16A, respectively. The cross-sections E-E and F-F correspond to cross-sections D-D and A-A in FIG. 1, respectively. Note that FIG. 16A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 16A illustrates two dummy gates 102 as a non-limiting example, the number of dummy gates 102 over the fins 90 may be any suitable number.

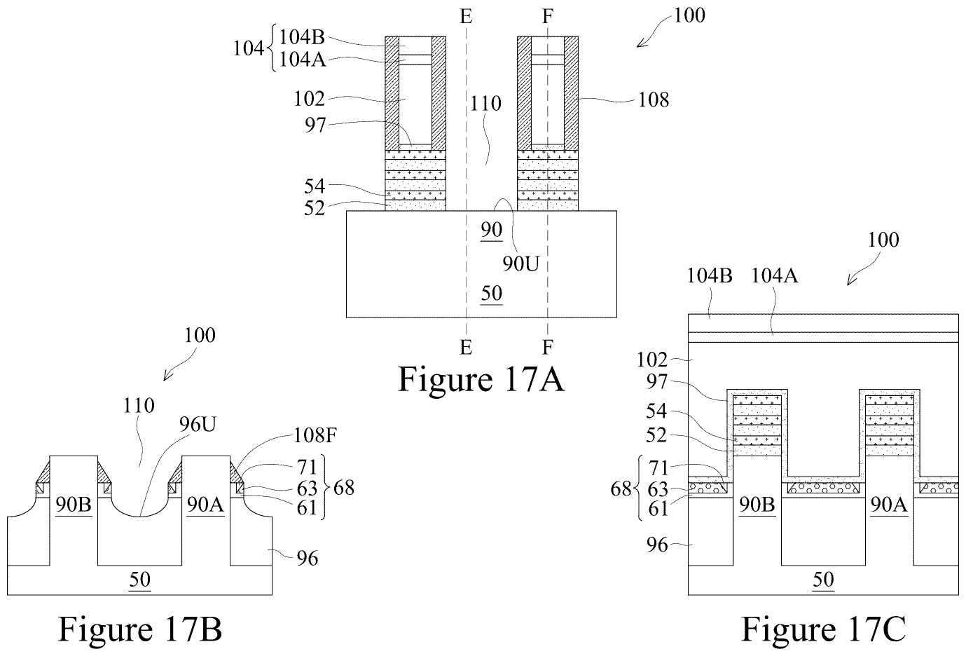

Next, in FIGS. 17A-17C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 along sidewalls of the dummy gates 102 and the dummy gate dielectric 97 forming the gate spacers 108. In addition, the remaining vertical portions of the gate spacer layer 108 along sidewalls of the fins 90 form fin spacers 108F (see, e.g., FIG. 17B).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask. Upper surfaces 90U of the fins 90 are exposed at the bottoms of the openings 110. Sidewalls of the openings 110 expose the first semiconductor material 52 and the second semiconductor material 54.

In the example of FIG. 17B, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 17B shows curved (e.g., concave) upper surfaces 96U of the STI regions 96 due to the etching of the STI regions 96. Note that portions of the STI protection structure 68 under (e.g., directly under) the dummy gates 102 are shielded from the anisotropic etching process, thus remain intact.

As illustrated in FIG. 17B, portions of the STI protection structure 68 remain under the fin spacers 108F, and are referred to as remaining portions of the STI protection structure 68. The remaining portions of the STI protection structure 68 protect the fins 90 from over-etching by the anisotropic etching process for forming the source/drain openings 110. Without the remaining portions of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions of the STI protection structure 68, avoids the above over-etching related issues, thereby preventing or reducing the likelyhood of device failure, and improving production yield. This illustrate another advantage of the presently disclosure.

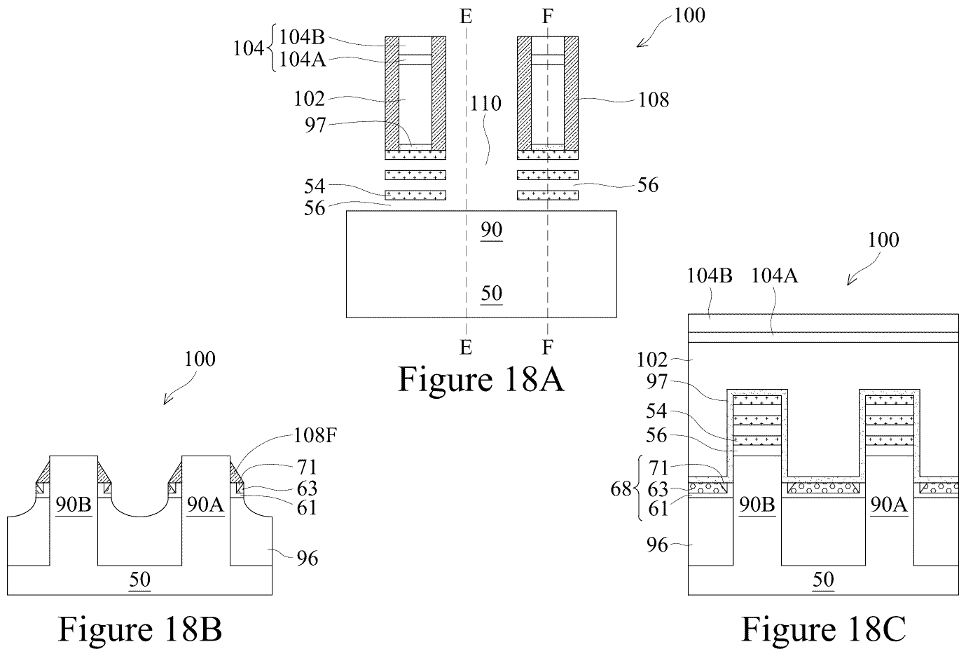

Next, in FIGS. 18A-18C, the first semiconductor material 52 under the dummy gates 102 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the STI regions 96, and the STI protection structure 68 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

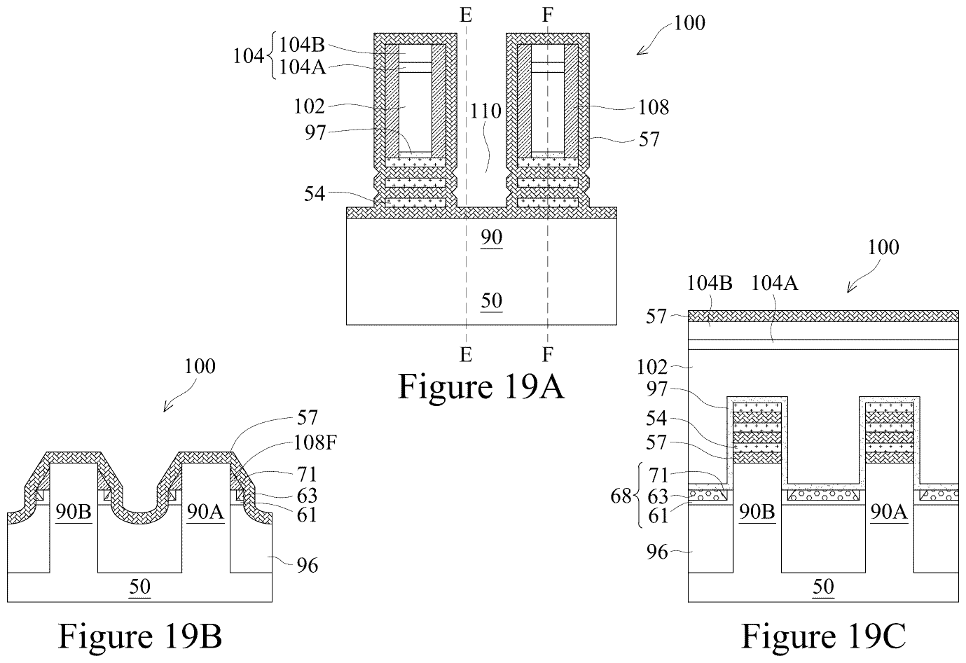

Next, in FIGS. 19A-19C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 is a dielectric material, in some embodiments. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the desired electrical and physical properties of the final product.

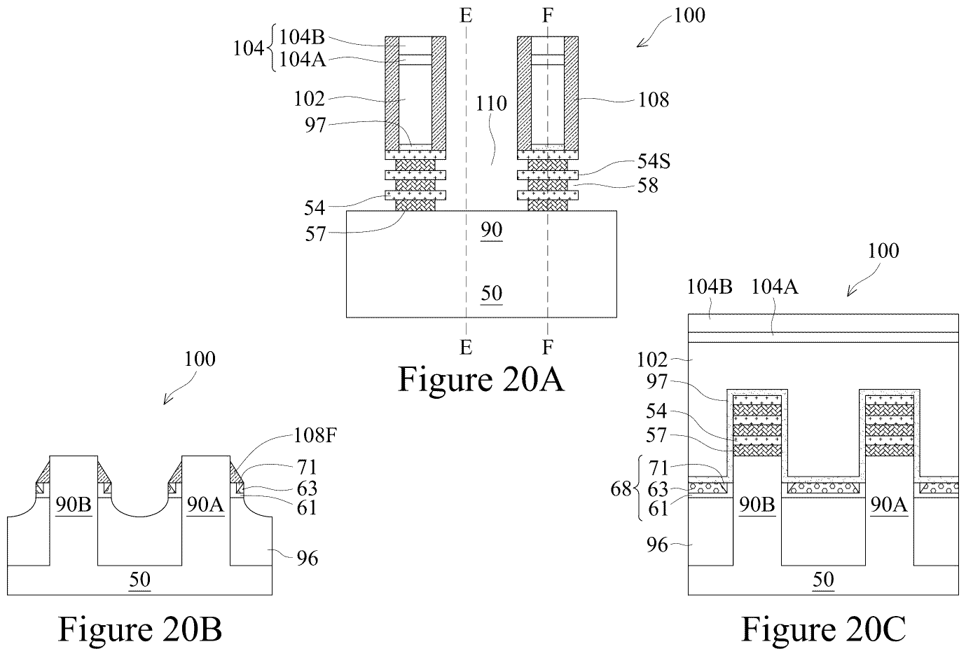

Next, in FIGS. 20A-20C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, may be referred to as disposable oxide interposers (DOIs). In the subsequent sheet formation process, the DOIs are selectively removed to release the layers of the second semiconductor material 54 to form nanostructures 54 (e.g., nanosheets, or nanowires). This process may be referred to as a DOI process.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provide excellent etching selectivity (e.g., higher than 10000) from the material (e.g. Si) of the second semiconductor material 54, thus allowing for selective removal of the DOIs in the sheet formation process with little or no damage to the nanostructures 54.

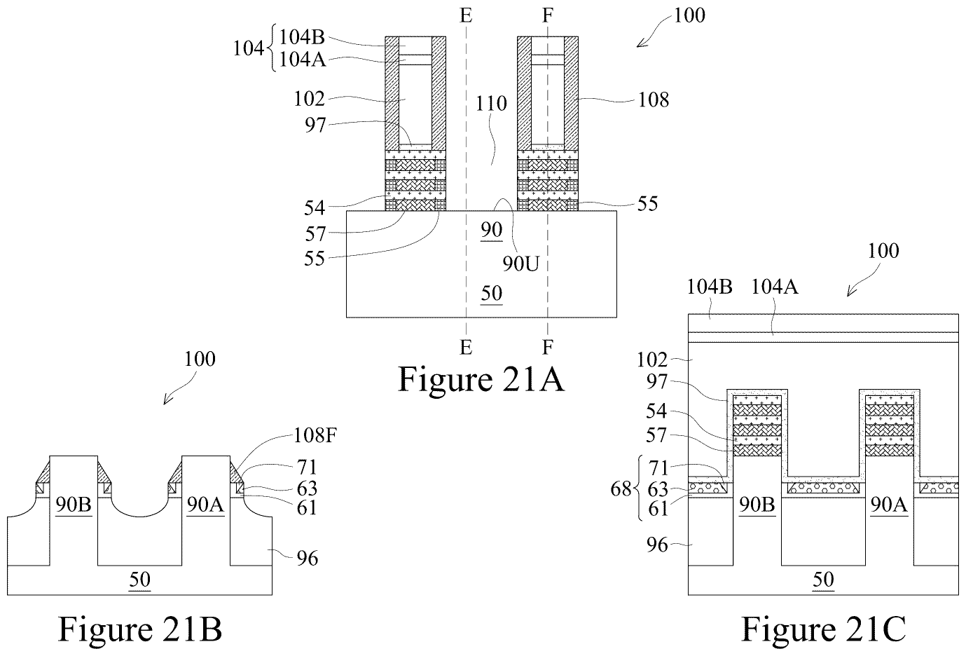

Next, in FIGS. 21A-21C, inner spacers 55 are formed in the sidewall recesses 58. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58) form inner spacers 55. As illustrated in FIG. 21A, the openings 110 expose sidewalls of the second semiconductor material 54 and expose upper surfaces 90U of the fins 90.

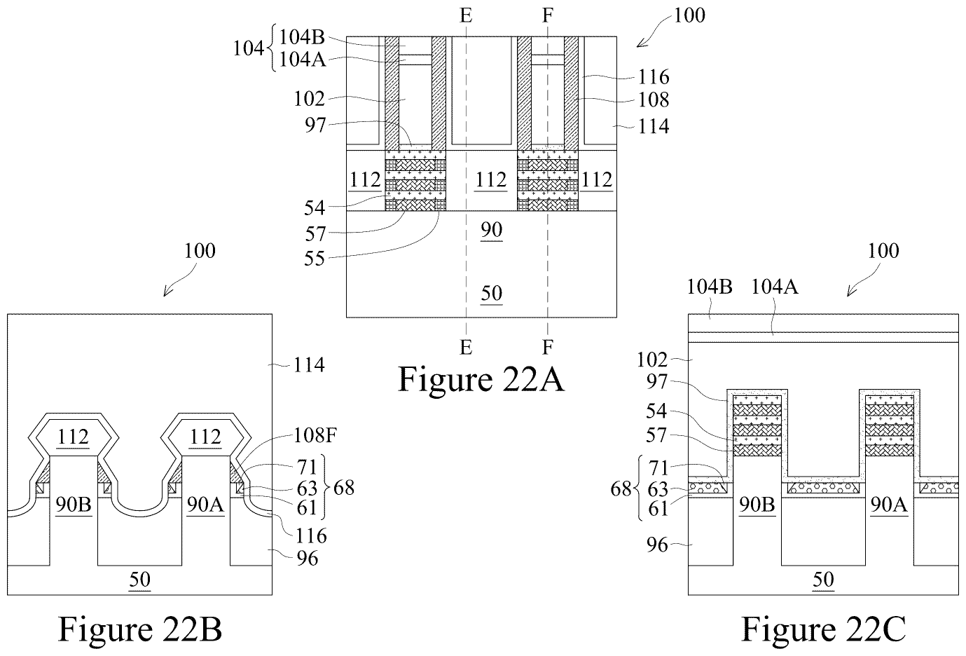

Next, in FIGS. 22A-22C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 22B. In other embodiments, these facets cause adjacent epitaxial source/drain regions 112 to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

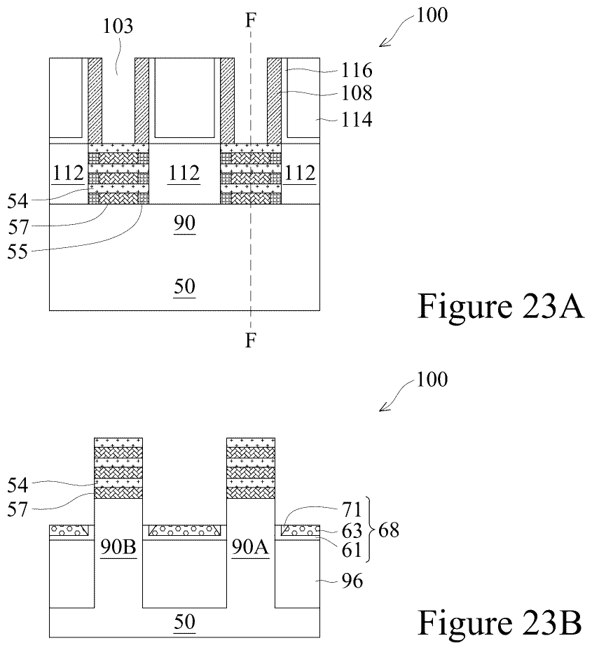

FIGS. 23A, 23B, 24A, 24B, 25A, and 25B illustrate a replacement gate process performed subsequently, where the dummy gate structures (e.g., 102 and 97) are removed and replaced by replacement gate structures 123 (e.g., metal gate structures). The cross-sectional views corresponding to FIG. 22B are not illustrated for the replacement gate process, because such cross-sectional views are the same as FIG. 22B, in some embodiments.

Next, in FIGS. 23A and 23B, the dummy gates 102 are removed in an etching step(s), so that recesses 103 (may also be referred to as gate trenches) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102.

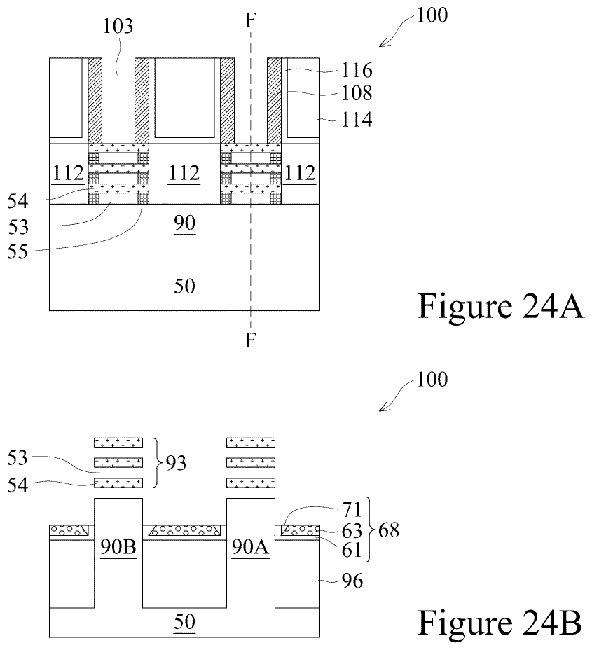

Next, in FIGS. 24A and 24B, the disposable material 57 is removed to release the second semiconductor material 54, which may be referred to as the sheet formation process. After the disposable material 57 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. As illustrated in FIGS. 24A and 24B, gaps 53 (e.g., empty spaces) are formed between the nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10000 or more is achieved between the disposable material 57 and the second semiconductor material 54. In other words, the disposable material 57 is removed by the isotropic etching process at an etch rate 10000 times or more than the etch rate of the second semiconductor material 54. As a result, the etching process (e.g., the sheet formation process) used to remove the disposable material 57 cause little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 disposed under the openings 103, thus causing recessing of the STI regions 96. The recessing of the STI regions 96 reduces the distance between the subsequent formed replacement gate structure and the substrate. In addition, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

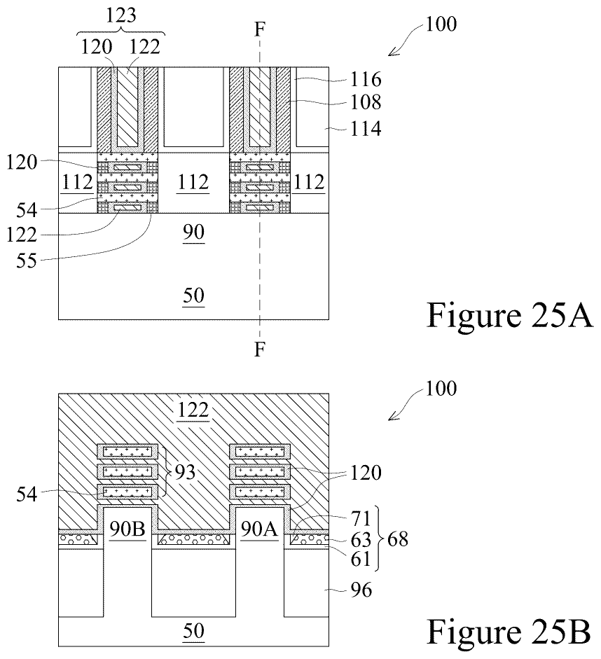

Next, in FIGS. 25A-25B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, on sidewalls of the gate spacers 108, and on the STI protection structure 68. The gate dielectric material 120 may also be formed on the top surfaces of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TIN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surfaces of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contact plugs and source/drain contact plugs may be formed to extend through the second ILD and/or the first ILD 114 to be electrically coupled to the gate structures 123 and the source/drain regions 112. Next, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices into separate individual devices. Details are not discussed here.

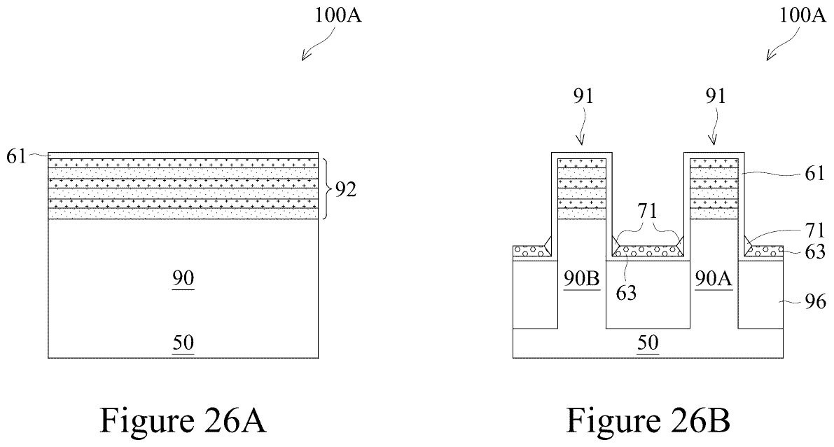

FIGS. 26A, 26B, 27A, 27B, 28A, and 28B are cross-sectional views of a portion of a nanostructure field-effect transistor (NSFET) device 100A at various stages of manufacturing, in accordance with another embodiment. The NSFET device 100A is similar to the NSFET device 100, but with concave upper surfaces for the STI protection structure 68.

The processing shown in FIGS. 26A and 26B follows the processing shown in FIGS. 13A and 13B, where a hard mask layer 71 is formed. Note that in the embodiment of NSFET device 100A, the material of the hard mask layer 71 has a higher density and/or a slower etch rate than the material of the hard mask layer 63. In FIGS. 26A and 26B, an etching process, which is the same as or similar to the etching process of FIGS. 14A and 14B, is performed to remove the hard mask layer 71 from the tops surfaces and the sidewalls of the layer stack 92, and from the upper surfaces of the hard mask layer 63. Remaining portions of the hard mask layer 71 are disposed over corner regions of the STI regions 96, and are disposed laterally between the liner layer 61 and the hard mask layer 63. Due to the density and/or the etch rate of the hard mask layer 71 relative to those of the hard mask layer 63, the remaining portions of the hard mask layer 71 are thicker (e.g., extend further from the substrate) than the hard mask layer 63. Therefore, at the bottom of a trench between adjacent fin structures 91, the remaining portions of the hard mask layer 71 and a portion of the hard mask layer 63 disposed in between form a structure with a concave upper surface.

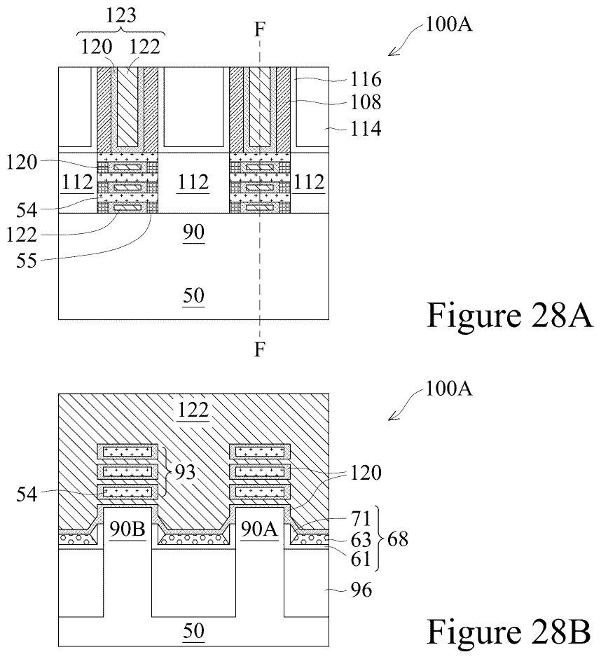

Next, in FIGS. 27A and 28B, portions of the liner layer 61 disposed above the hard mask layer 63 and the remaining portions of the hard mask layer 71 are removed by an etching process. The etching process may be the same as or similar to the etching process of FIGS. 15A and 15B, thus details are not repeated. After the etching process, the remaining portions of the liner layer 61, the hard mask layer 63, and the remaining portions of the hard mask layer 71 form the STI protection structure 68. Notably in FIG. 27B, the upper surfaces of the STI protection structure 68 are concave upper surfaces.

Next, the processing steps illustrated in FIGS. 16A-16C, 17A-17C, 18A-18C, 19A-19C, 20A-20C, 21A-21C, 22A-22C, 23A, 23B, 24A, 24B, 25A, and 25B are performed to form the NSFET device 100A. FIGS. 28A and 28B illustrates the cross-sectional views of the NSFET device 100A after the replacement gate structures 123 are formed. In other words, the processing step of FIGS. 28A and 28B correspond to that of FIGS. 25A and 25B. As illustrated in FIG. 28B, the gate dielectric layer 120 contacts and extends along the concave upper surfaces of the STI protection structure 68.

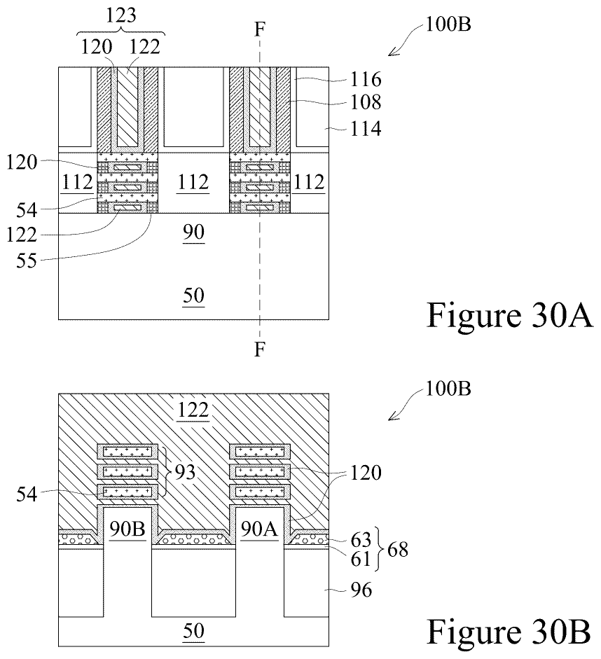

FIGS. 29A, 29B, 30A, and 30B are cross-sectional views of a portion of a nanostructure field-effect transistor (NSFET) device 100B at various stages of manufacturing, in accordance with yet another embodiment. The NSFET device 100B is similar to the NSFET device 100, but with convex upper surfaces for the STI protection structure 68.

The processing shown in FIGS. 29A and 29B follows the processing shown in FIGS. 12A and 12B. Note that the hard mask layer 71 of NSFET device 100 is omitted in the fabrication process of the NSFET device 100. The etching process same as or similar to that of FIGS. 15A and 15B is performed to remove the liner layer 61 from the top surface and the sidewalls of the layer stack 92. The remaining portions of the liner layer 61 and the hard mask layer 63 form the STI protection structure 68. As illustrated in FIG. 29B, the STI protection structure 68 have convex upper surfaces, which convex upper surfaces are formed because the bottom portions 63 of the hard mask layer 66 has a higher density and/or a lower etch rate, as discussed above, in some embodiments.

Next, the processing steps illustrated in FIGS. 16A-16C, 17A-17C, 18A-18C, 19A-19C, 20A-20C, 21A-21C, 22A-22C, 23A, 23B, 24A, 24B, 25A, and 25B are performed to form the NSFET device 100B. FIGS. 30A and 30B illustrates the cross-sectional views of the NSFET device 100B after the replacement gate structures 123 are formed. In other words, the processing step of FIGS. 30A and 30B correspond to that of FIGS. 25A and 25B. As illustrated in FIG. 30B, the gate dielectric layer 120 contacts and extends along the convex upper surfaces of the STI protection structure 68.

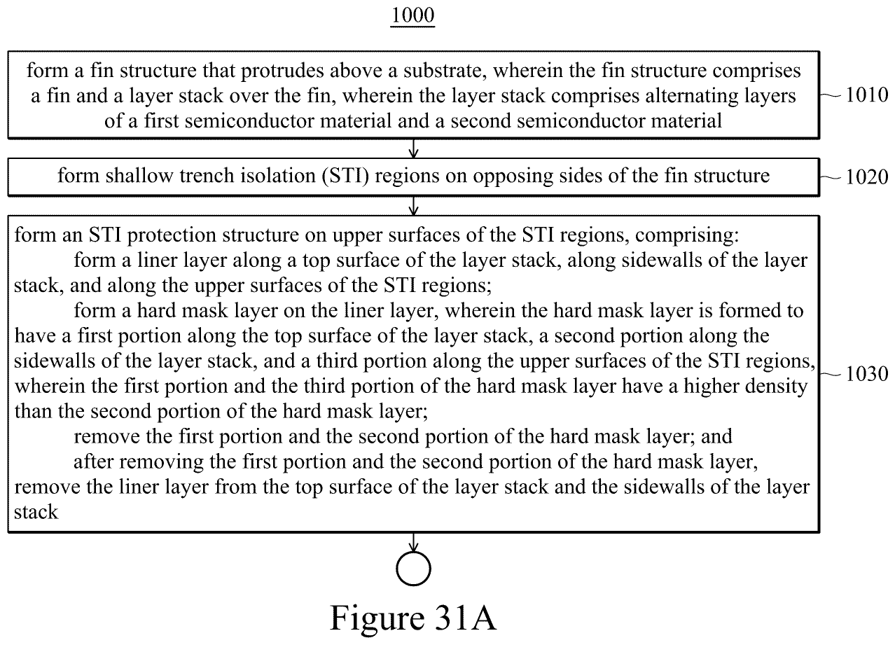

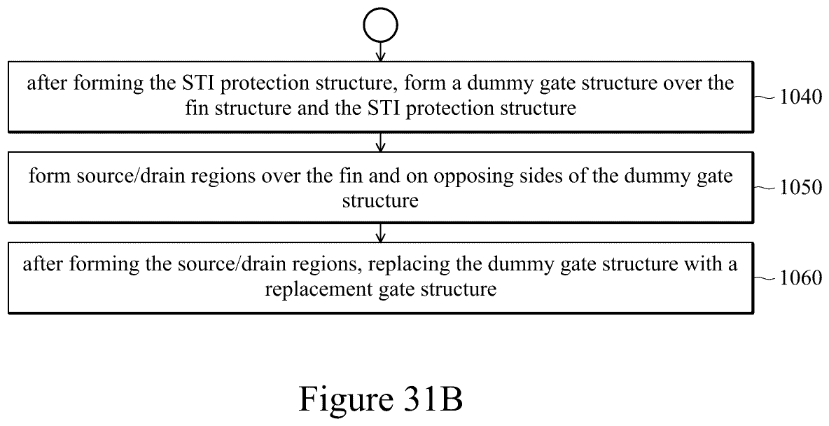

FIGS. 31A and 31B together illustrate a flow chart of a method 1000 of forming a semiconductor device, in accordance with some embodiments. It should be understood that the embodiment method shown in FIGS. 31A and 31B is merely an example of many possible embodiment methods. One of ordinary skill in the art would recognize many variations, alternatives, and modifications. For example, various steps as illustrated in FIGS. 31A and 31B may be added, removed, replaced, rearranged, or repeated.

Referring to FIGS. 31A and 31B, at block 1010, a fin structure that protrudes above a substrate is formed, wherein the fin structure comprises a fin and a layer stack over the fin, wherein the layer stack comprises alternating layers of a first semiconductor material and a second semiconductor material. At block 1020, shallow trench isolation (STI) regions are formed on opposing sides of the fin structure. At block 1030, an STI protection structure is formed on upper surfaces of the STI regions, comprising: forming a liner layer along a top surface of the layer stack, along sidewalls of the layer stack, and along the upper surfaces of the STI regions; forming a hard mask layer on the liner layer, wherein the hard mask layer is formed to have a first portion along the top surface of the layer stack, a second portion along the sidewalls of the layer stack, and a third portion along the upper surfaces of the STI regions, wherein the first portion and the third portion of the hard mask layer have a higher density than the second portion of the hard mask layer; removing the first portion and the second portion of the hard mask layer; and after removing the first portion and the second portion of the hard mask layer, removing the liner layer from the top surface of the layer stack and the sidewalls of the layer stack. At block 1040, after forming the STI protection structure, a dummy gate structure is formed over the fin structure and the STI protection structure. At block 1050, source/drain regions are formed over the fin and on opposing sides of the dummy gate structure. At block 1060, after forming the source/drain regions, the dummy gate structure is replaced with a replacement gate structure.

As discussed above, the STI protection structure 68 disclosed herein protects the STI regions 96 disposed under the dummy gate structures during the sheet formation process, and prevents or reduces loss of the STI regions 96. Further improvements to the STI protection structure 68 are possible, e.g., by improving the quality and/or etch resistance of the liner layer 61. Various embodiments are disclosed hereinafter.

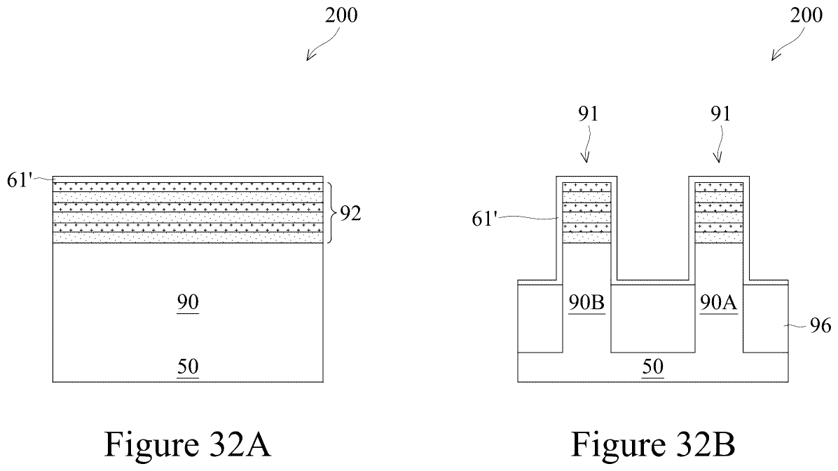

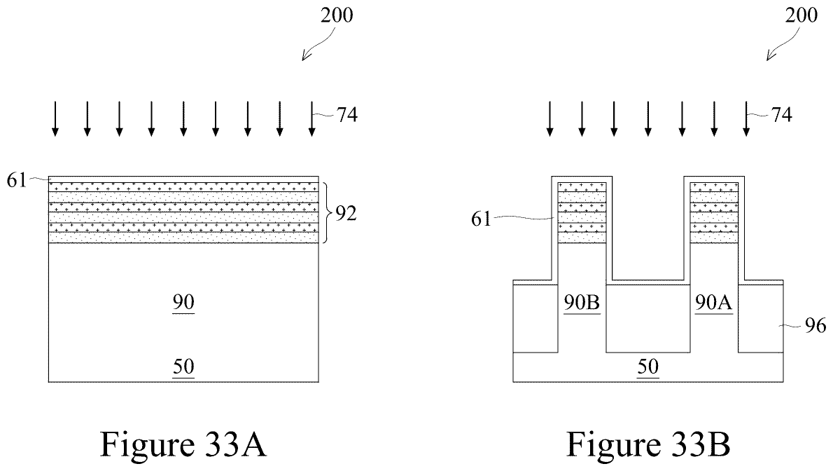

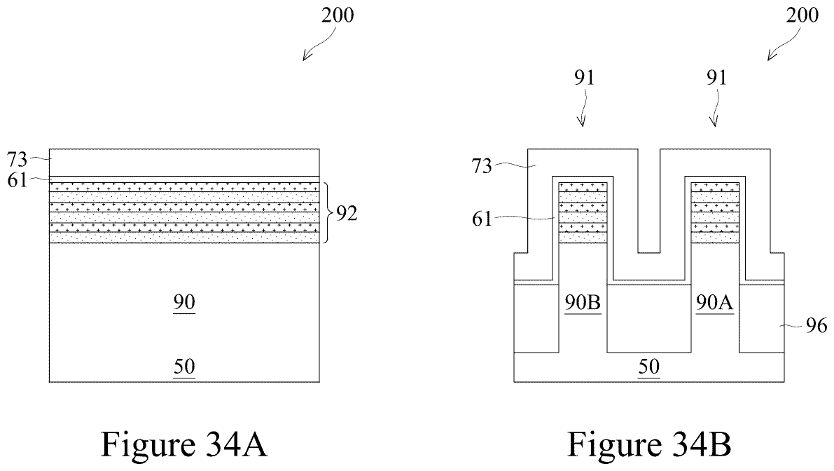

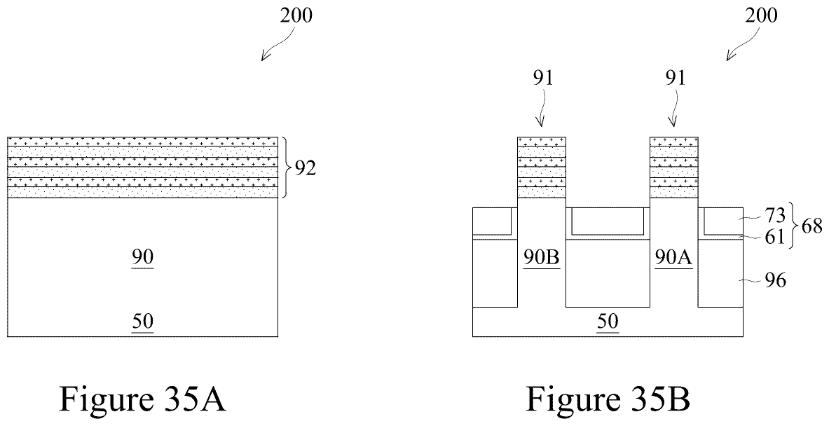

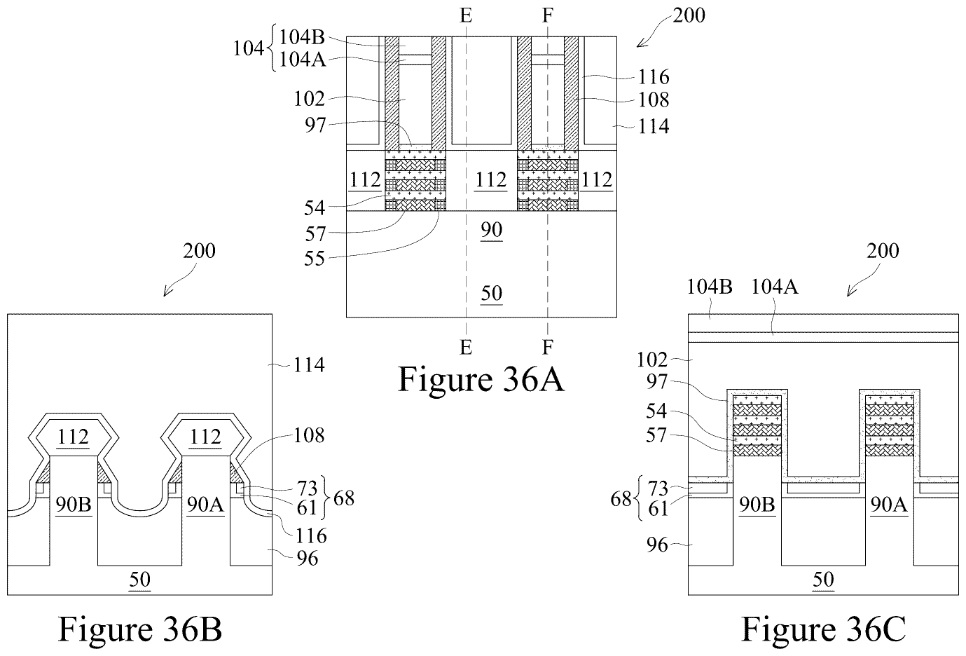

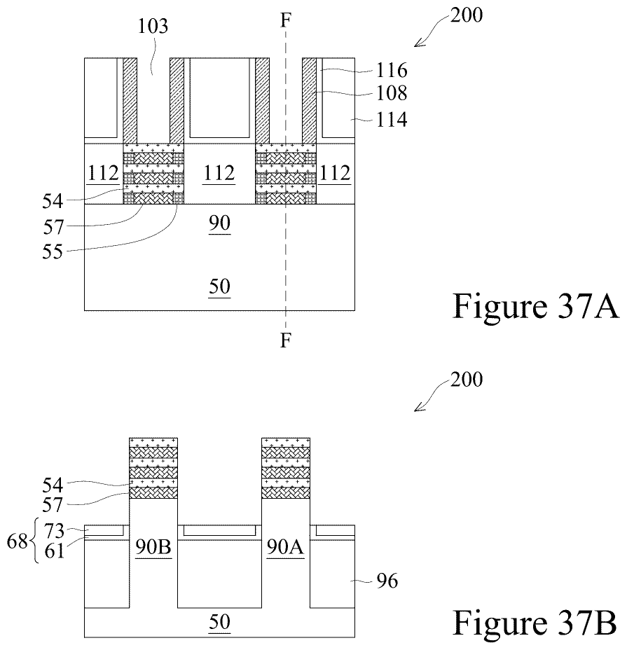

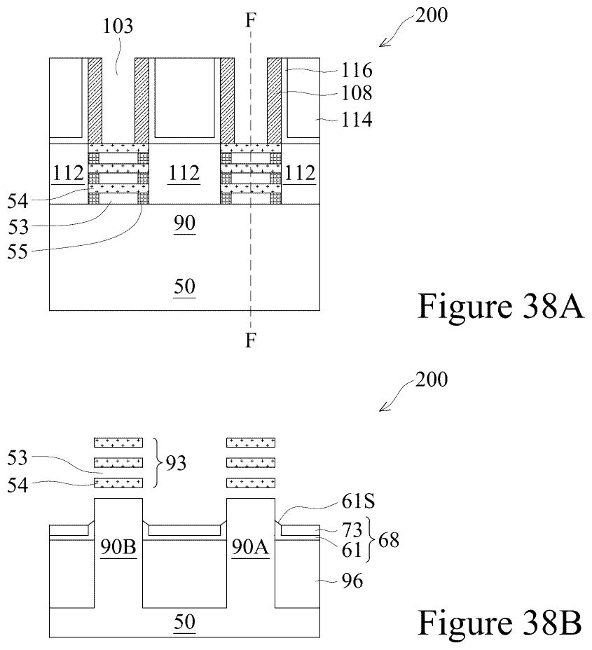

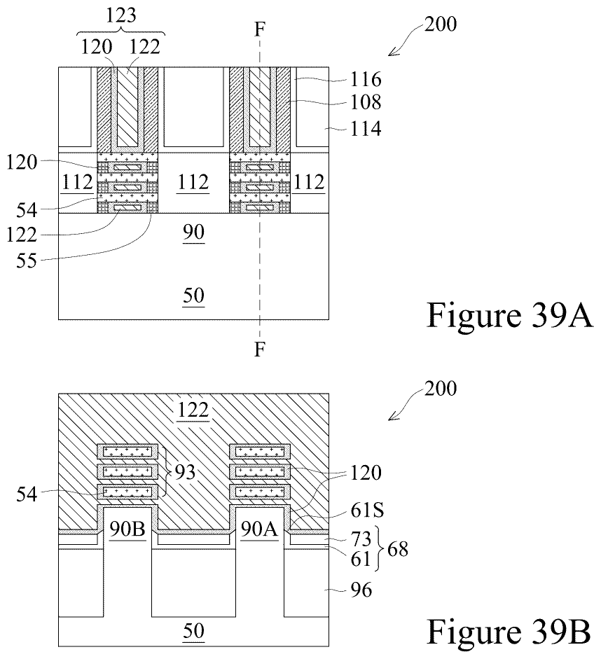

FIGS. 32A, 32B, 33A, 33B, 34A, 34B, 35A, 35B, 36A, 36B, 36C, 37A, 37B, 38A, 38B, 39A, and 39B are cross-sectional views of a portion of a nanostructure field-effect transistor (NSFET) device 200 at various stages of manufacturing, in accordance with an embodiment. The NSFET device 200 is similar to the NSFET device 100, but with a different formation process for the STI protection structure 68. For brevity, discussion below focuses on the differences between the NSFET devices 100 and 200, and details of the processing steps common to both the NSFET devices 100 and 200 may not be repeated.

FIGS. 32A, 33A, 34A, 35A, 36A, 37A, 38A, and 39A are cross-sectional views along cross-section B-B in FIG. 1. FIGS. 32B, 33B, 34B, 35B, 36C, 37B, 38B, and 39B are cross-sectional views along cross-section A-A in FIG. 1. FIG. 16B is a cross-sectional view along cross-section D-D in FIG. 1.

The processing of FIGS. 32A and 32B follows the processing of FIGS. 3A and 3B. In FIGS. 32A and 32B, STI regions 96 are formed, following the same or similar processing for forming STI regions 96 in FIGS. 4A and 4B. Next, a liner layer 61′ is formed over the layer stacks 92 and over the STI regions 96. The liner layer 61′ may be a suitable dielectric material such as silicon oxide, and may be formed using a suitable deposition method such as CVD, ALD, or the like.

Next, in FIGS. 33A and 33B, the liner layer 61′ is treated by a plasma process 74. The plasma process 74 changes or enhances the properties of the liner layer 61′, and turns the liner layer 61′ into a liner layer 61.

In an embodiment, the plasma process 74 is an isotropic plasma process performed using an oxygen-containing gas source, such as a gas source comprising oxygen gas (O₂) or carbon dioxygen gas (CO₂). A carrier gas, such as argon, may be included in the gas source. The gas source is ignited into a plasma by an RF power source, and the plasm is used to treat the liner layer 61′. Process conditions of the plasma process 74 are tuned to achieve isotropicity of the plasma process 74. In some embodiments, the plasma of the gas source is filtered by an ion filter, and oxygen ions pass through the ion filter and are used to treat the liner layer 61′. In some embodiments, the liner layer 61′ (e.g., silicon oxide) has defects, such as having dangling bonds (Si—O dangling bonds) at the surfaces of the liner layer 61′, and the oxygen ions repair the dangling bonds to form silicon oxide of higher quality (e.g., less defects), which is more resistant to the subsequent etching process of, e.g., the sheet formation process. The carbon (e.g., carbon ions) in the plasma may be used to control the reaction rate of the isotropic plasma process.

In some embodiments, the isotropic plasma process is performed at a temperature between about 75° C. and about 390° C. The pressure of the isotropic plasma process may be between about 2 torr and about 5 torr. The power of the RF power source may be between about 15 W and about 500 W, and the processing time of the isotropic plasma process may be between about 10 seconds and about 60 seconds.

In an embodiment, the plasma process 74 is an anisotropic plasma process performed using a nitrogen-containing gas source, such as a gas source comprising nitrogen gas (N₂) or ammonia (NH₃). A carrier gas, such as argon, may be included in the gas source. The gas source is ignited into a plasma by an RF power source, and the plasm is used to treat the liner layer 61′. Process conditions of the plasma process 74 are tuned to achieve anisotropicity of the plasma process 74. In some embodiments, the plasma of the gas source is used to nitridize the liner layer 61′ (e.g. silicon oxide), and turns the liner layer 61′ into the liner layer 61, which is a layer of nitride (e.g., silicon oxynitride). The liner layer 61 is more resistant (e.g., having a lower etch rate) to the subsequent etching process(es) than the liner layer 61′.

In some embodiments, the anisotropic plasma process is performed at a temperature between about 260° C. and about 450° C. The pressure of the anisotropic plasma process may be between about 3.5 torr and about 8 torr. The power of the RF power source may be between about 500 W and about 1300 W, and the processing time of the anisotropic plasma process may be between about 20 seconds and about 3 minutes.

In an embodiment, the plasma process 74 is an ion implantation process. Nitrogen ions (e.g., N+ ions) are implanted into the liner layer 61′ and turns the liner layer 61′ into the liner layer 61 (e.g., silicon oxynitride). In other words, the ion implantation process nitridizes the liner layer 61′.

In some embodiments, the implantation process is performed using nitrogen ions with energy between about 0.8 keV and about 1.2 keV. The dosage of the ion implantation process is between about 10¹⁵ cm⁻² and 3×10¹⁵ cm⁻², and the implantation angle is between about 0.5 degree and about 3 degrees. An anneal process, such as a spike anneal, may be performed after the ion implantation process at a temperature between about 800° C. and about 900° C. for a duration between about 20 seconds and about 60 seconds.

Next, in FIGS. 34A and 34B, a hard mask layer 73 is formed (e.g., conformally) over the liner layer 61. The hard mask layer 73 may be formed of silicon nitride, silicon oxynitride, silicon carbonitride, silicon oxycarbonitride, or the like, and may be formed of a suitable formation method, such as CVD, ALD, or the like.

Next, a plurality of etching processes are performed to recesses the liner layer 61 and the hard mask layer 73, e.g., by removing the liner layer 61 and the hard mask layer 73 from the top surfaces and the sidewalls of the layer stacks 92. For example, processing steps same as or similar to those of FIGS. 8A-12B may be performed to recess the hard mask layer 73. Then, the liner layer 61 disposed above the remaining portions of the hard mask layer 73 is removed by an etching process. The remaining portions of the hard mask layer 73 and the remaining portions of the liner layer 61 form the STI protection structure 68. In the example of FIG. 35B, the STI protection structure 68 has flat upper surfaces.

Next, following the same or similar processing steps of FIGS. 16A-22C, dummy gates 102 and dummy gate dielectric 97 are formed over the fin structures 91. Gate spacers 108 are formed to extend along sidewalls of the dummy gates 102. The sacrificial material 57 is formed to replace the first semiconductor materials 52 disposed under the dummy gates 102. Inner spacers 55 are formed at opposing ends of the sacrificial material 57. Source/drain regions 112 are formed on opposing sides of the dummy gates 102. CESL 116 and first ILD 114 are formed over the source/drain regions 112 and the dummy gates 102. FIGS. 36A-36C illustrate cross-sectional views of the NSFET device 200 after the CESL 116 and the first ILD 114 are formed.

Next, a replacement gate process, illustrated in FIGS. 37A-39B, is performed to replace the dummy gate structures with replacement gate structures 123. The details are the same as or similar to those discussed above, thus may not be repeated.

In FIGS. 37A and 37B, the dummy gate structures are removed to form recesses 103 (e.g., gate trenches) between gate spacers 108.

Next, in FIGS. 38A and 38B, the sacrificial material 57 is removed in the sheet formation process to release the second semiconductor material 54, thus forming nanostructures 54. Empty spaces 53 are formed at locations where the sacrificial material 57 used to be. In the example of FIG. 38B, after the etching process used for the sheet formation process, the liner layer 61 has sloped upper surfaces 61S. The sloped upper surfaces 61S of the liner layer 61 extend further from the substrate 50 than the upper surfaces of the remaining portions of the hard mask layer 73.

The sloped, higher upper surfaces 61S of the STI protection structure 68 in FIG. 38B illustrate an advantage of the disclosed embodiments. Without the treatment of the plasma process 74, the liner layer in the STI protection structure 68 would be the liner layer 61′, which is typically an oxide (e.g., silicon oxide). Since silicon oxide is less etch resistant than the material of the hard mask layer 73 (e.g., silicon nitride), the liner layer 61′ may become a weak point in the STI protection structure 68. In the sheet formation process, the liner layer (e.g., silicon oxide) at corner regions of the STI protection structure 68 may be etched through and cause damage to the fins 90. When the subsequently formed replacement gate structure fills the empty spaces at the corner regions (left by the removed liner layer), protrusion of the gate structure occurs, which increases the parasitic capacitance of the gate structure formed. The disclosure plasma process 74 improve the etching resistance of the liner layer 61′ and turns the liner layer 61′ into a more etch resistant liner layer 61. As a result, the issues discussed above relating to the weak liner layer are avoided or alleviated. The higher upper surfaces 61S of the liner layer 61 of the STI protection structure 68 after the sheet formation process, as illustrated in FIG. 38B, demonstrate the effectiveness of the plasma treatment (e.g., plasma process 74) for the liner layer 61′.

Next, in FIGS. 39A and 39B, gate dielectric layers 120 are formed around the nanostructures 54, and gate electrodes 122 are formed around the gate dielectric layers 120 to form replacement gate structures 123. Details are discussed above, thus not repeated here.

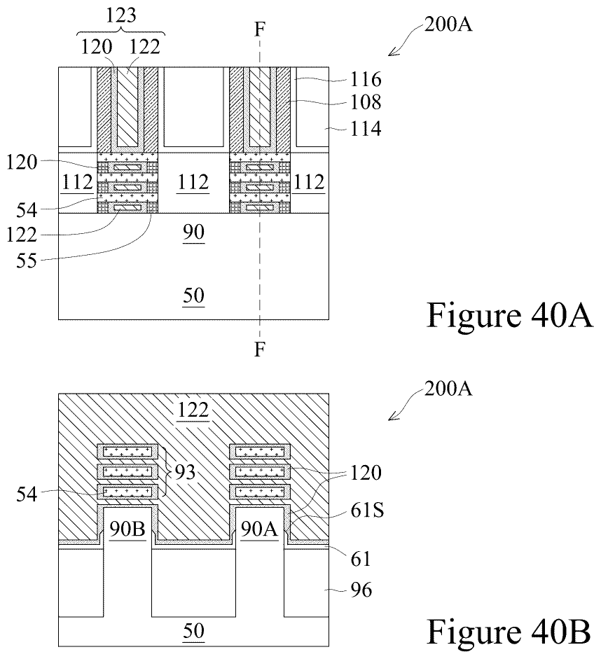

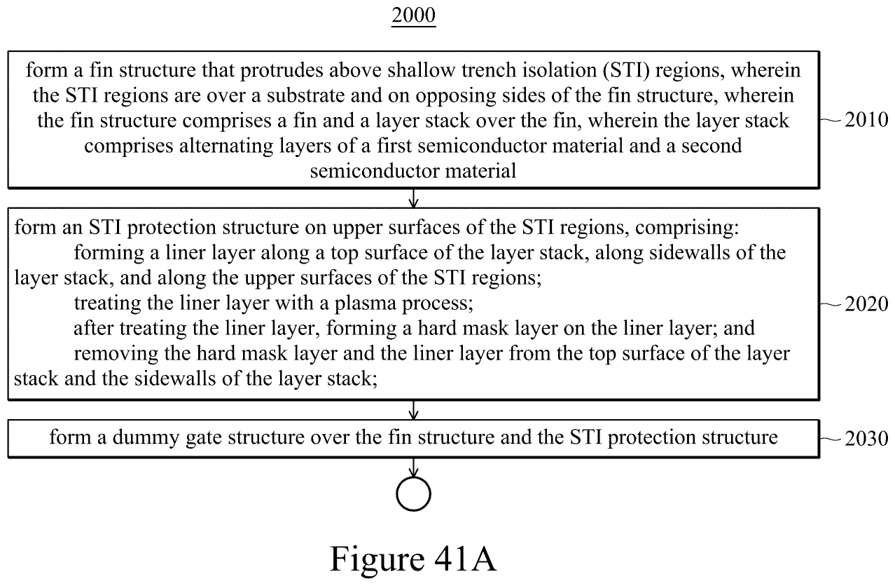

FIGS. 40A and 40B are cross-sectional views of a portion of a nanostructure field-effect transistor (NSFET) device 200A, in accordance with another embodiment. The NSFET device 200A is similar to the NSFET device 200, but in the final product, only the liner layer 61 of the STI protection structure 68 remains. In the example of FIG. 40B, the liner layer 61 has sloped upper surface 61S, similar to those in FIG. 38B. In some embodiments, the sheet formation process of the NSFET device 200A uses a wet etching process to remove the sacrificial material 57. The etchant (e.g., H₃PO₄) used in the wet etching process may etch away (e.g., completely removes) the hard mask layer 73 (see FIG. 39B) in the STI protection structure 68, and the liner layer 61 of the STI structure 68 remains in the NSFET device 200A, as shown in FIGS. 40A and 40B. In contrast, the STI protection structure 68 in FIG. 38B still has the hard mask layer 73, which may due to the etchant used in the sheet formation process for the NSFET device 200, such as diluted hydrofluoric acid (dHF), buffer HF (a mixture of hydrofluoric acid (HF) and ammonium fluoride (NH₄F)), or fluorine-containing peroxide mixture (FPM) (a mixture of hydrogen peroxide (H₂O₂) and hydrofluoric acid (HF)).

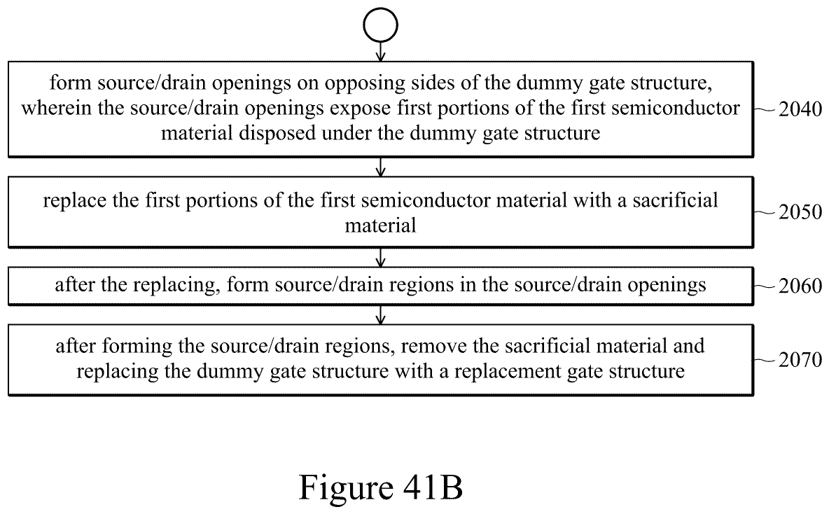

FIGS. 41A and 41B together illustrate a flow chart of a method 2000 of forming a semiconductor device, in some embodiments. It should be understood that the embodiment method shown in FIGS. 41A and 41B is merely an example of many possible embodiment methods. One of ordinary skill in the art would recognize many variations, alternatives, and modifications. For example, various steps as illustrated in FIGS. 41A and 41B may be added, removed, replaced, rearranged, or repeated.

Referring to FIGS. 41A and 41B, at block 2010, a fin structure that protrudes above shallow trench isolation (STI) regions is formed, wherein the STI regions are over a substrate and on opposing sides of the fin structure, wherein the fin structure comprises a fin and a layer stack over the fin, wherein the layer stack comprises alternating layers of a first semiconductor material and a second semiconductor material. At block 2020, an STI protection structure is formed on upper surfaces of the STI regions, comprising: forming a liner layer along a top surface of the layer stack, along sidewalls of the layer stack, and along the upper surfaces of the STI regions; treating the liner layer with a plasma process; after treating the liner layer, forming a hard mask layer on the liner layer; and removing the hard mask layer and the liner layer from the top surface of the layer stack and the sidewalls of the layer stack. At block 2030, a dummy gate structure is formed over the fin structure and the STI protection structure. At block 2040, source/drain openings are formed on opposing sides of the dummy gate structure, wherein the source/drain openings expose first portions of the first semiconductor material disposed under the dummy gate structure. At block 2050, the first portions of the first semiconductor material are replaced with a sacrificial material. At block 2060, after the replacing, source/drain regions are formed in the source/drain openings. At block 2070, after forming the source/drain regions, the sacrificial material is removed and the dummy gate structure is replaced with a replacement gate structure.

Advantages are achieved by the disclosed embodiments. For example, the use of the DOI process reduces intermixing between germanium and silicon, and provides significantly higher etching selectivity (e.g., >10000) between the disposable material 57 and the second semiconductor material 54. As a result, when the sacrificial material 57 is removed to form the nanostructures 54, there is little or no damage to the nanostructures. As another example, the disclosed STI protection structure 68 protects the STI regions 96 (e.g., portions under the dummy gates) during the removal of the sacrificial material 57, and as a result, loss of the STI region 96 is avoided or reduced, which reduces the parasitic capacitance of the replacement gate structure 123 and improves device performance. As yet another example, the remaining portions of the STI protection structure 68 under the fin spacers 108F prevents or reduces the likelyhood of the fins 90 collapsing or un-intended growth/merging of source/drain material due to over-etching of the STI regions 96. As a result, device failure is avoided and production yield is increased.

Variations and modification to the disclosed embodiments are possible and are fully intended to be included within the scope of the present disclosure. The examples of NSFET devices 100, 100A, and 100B focus on the hard mask layer(s) in the STI protection structure 68 to achieve the various profiles for the upper surfaces of the STI protection structure, and the examples of NSFET devices 200 and 200A focus on enhancing the liner layer of the STI protection structure. Skilled artisans would readily appreciate that the various aspects of the disclosed embodiments can be combined. For example, the plasma process 74 used for the NSFET device 200 may be used for enhancing the liner layer 61 of the NSFET devices 100, 100A, and 100B, thereby resulting in more etch resistant liner layer 61, and at the same time, achieving various profiles (e.g., concave/convex/flat upper surfaces) for the STI protection structure 68.

In an embodiment, a method of forming a semiconductor device includes: forming a fin structure that protrudes above a substrate, wherein the fin structure comprises a fin and a layer stack over the fin, wherein the layer stack comprises alternating layers of a first semiconductor material and a second semiconductor material; forming shallow trench isolation (STI) regions on opposing sides of the fin structure; and forming an STI protection structure on upper surfaces of the STI regions, which includes: forming a liner layer along a top surface of the layer stack, along sidewalls of the layer stack, and along the upper surfaces of the STI regions; forming a hard mask layer on the liner layer, wherein the hard mask layer is formed to have a first portion along the top surface of the layer stack, a second portion along the sidewalls of the layer stack, and a third portion along the upper surfaces of the STI regions, wherein the first portion and the third portion of the hard mask layer have a higher density than the second portion of the hard mask layer; removing the first portion and the second portion of the hard mask layer; and after removing the first portion and the second portion of the hard mask layer, removing the liner layer from the top surface of the layer stack and the sidewalls of the layer stack. The method further includes: after forming the STI protection structure, forming a dummy gate structure over the fin structure and the STI protection structure; forming source/drain regions over the fin and on opposing sides of the dummy gate structure; and after forming the source/drain regions, replacing the dummy gate structure with a replacement gate structure. In an embodiment, forming the source/drain regions comprises: forming source/drain openings in the fin structure on the opposing sides of the dummy gate structure, wherein the source/drain openings expose the first semiconductor material and the second semiconductor material; and forming the source/drain regions in the source/drain openings. In an embodiment, the method further includes, after forming the source/drain openings and before forming the source/drain regions, replacing the first semiconductor material disposed under the dummy gate structure with a sacrificial material. In an embodiment, replacing the dummy gate structure comprises: removing the dummy gate structure to expose the sacrificial material and a first portion of the second semiconductor material; removing the exposed sacrificial material, wherein after removing the exposed sacrificial material, the first portion of the second semiconductor material remains to form channel regions of the semiconductor device; and forming a gate dielectric material and a gate electrode material around the channel regions. In an embodiment, forming the hard mask layer comprises performing a plurality of deposition cycles, wherein each deposition cycle of the plurality of deposition cycles is performed by: depositing a first layer of material on the liner layer; and treating the first layer of material using an anisotropic plasma process, wherein the anisotropic plasma process turns the first layer of material into a second layer of material, wherein the second layer of material and the first layer of material have different material compositions. In an embodiment, the first layer of material comprises silicon, the anisotropic plasma process is performed using a gas source comprising nitrogen. In an embodiment, after removing the liner layer, a remaining portion of the liner layer along the upper surfaces of the STI regions and the third portion of the hard mask layer form the STI protection structure. In an embodiment, the STI protection structure has a convex upper surface distal from the substrate. In an embodiment, forming the STI protection structure further comprises, after removing the first portion and the second portion of the hard mask layer and before removing the liner layer: forming another hard mask layer along the top surface of the layer stack, along the sidewalls of the layer stack, along sidewalls of the fin, and along an upper surface of the third portion of the hard mask layer; and performing an etching process to remove the another hard mask layer from the top surface of the layer stack, the sidewalls of the layer stack, and the upper surface of the third portion of the hard mask layer, wherein after performing the etching process, a remaining portion of the another hard mask layer is disposed laterally between the liner layer and the third portion of the hard mask layer, wherein after removing the liner layer, the remaining portion of the another hard mask layer, the third portion of the hard mask layer, and a remaining portion of the liner layer along the upper surfaces of the STI regions remain to form the STI protection structure. In an embodiment, the another hard mask layer has a higher density than the hard mask layer, and the STI protection structure has a concave upper surface distal from the substrate. In an embodiment, the another hard mask layer has a same density as the hard mask layer, and the STI protection structure has a flat upper surface distal from the substrate.

In an embodiment, a method of forming a semiconductor device includes: forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material; and forming an STI protection structure on upper surfaces of the STI regions, which includes: forming a liner layer along a top surface of the layer stack, along sidewalls of the layer stack, and along the upper surfaces of the STI regions; forming a hard mask layer on the liner layer, comprising: forming a first layer of material on the liner layer; and performing an anisotropic plasma process to treat the first layer of material, wherein the anisotropic plasma process turns the first layer of material into a second layer of material having a different material composition from the first layer of material; removing the hard mask layer from the top surface of the layer stack and the sidewalls of the layer stack; and after removing the hard mask layer, removing the liner layer from the top surface of the layer stack and the sidewalls of the layer stack, wherein after removing the liner layer, a remaining portion of the liner layer and a remaining portion of the hard mask layer cover the upper surfaces of the STI regions. The method further includes: forming a dummy gate structure over the fin structure and the STI protection structure; forming source/drain regions on opposing sides of the dummy gate structure; and after forming the source/drain regions, replacing the dummy gate structure with a replacement gate structure. In an embodiment, the hard mask layer is formed to include a first portion along the top surface of the layer stack, a second portion along the sidewalls of the layer stack, and a third portion along the upper surfaces of the STI regions, wherein the first portion and the third portion of the hard mask layer have a higher density than the second portion of the hard mask layer. In an embodiment, forming the STI protection structure further comprises, after removing the hard mask layer and before removing the liner layer: forming another hard mask layer along the top surface of the layer stack, along the sidewalls of the layer stack, along sidewalls of the fin, and along an upper surface of the remaining portion of the hard mask layer; and performing an etching process to remove the another hard mask layer from the top surface of the layer stack, the sidewalls of the layer stack, and the upper surface of the remaining portion of the hard mask layer, wherein after performing the etching process, a remaining portion of the another hard mask layer is disposed laterally between the liner layer and the remaining portion of the hard mask layer. In an embodiment, after removing the liner layer, the remaining portion of the liner layer extend along the sidewalls of the fin and along the upper surfaces of the STI regions, wherein the remaining portion of the another hard mask layer, the remaining portion of the hard mask layer, and the remaining portion of the liner layer form the STI protection structure. In an embodiment, forming the source/drain regions comprises: forming source/drain openings in the fin structure on the opposing sides of the dummy gate structure; after forming the source/drain openings, replacing the first semiconductor material disposed under the dummy gate structure with a sacrificial material; and after the replacing, forming the source/drain regions in the source/drain openings. In an embodiment, replacing the dummy gate structure comprises: forming an interlayer dielectric (ILD) layer over the source/drain regions around the dummy gate structure; removing the dummy gate structure to form a gate trench in the ILD layer, wherein the gate trench exposes the sacrificial material and a first portion of the second semiconductor material; selectively removing the exposed sacrificial material, wherein after the selectively removing, the first portion of the second semiconductor material remain to form nanostructures; and forming a gate dielectric material and a gate electrode material around the nanostructures.

In an embodiment, a method of forming a semiconductor device includes: forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material; and forming an STI protection structure on upper surfaces of the STI regions, which includes: forming a liner layer along a top surface of the layer stack, along sidewalls of the layer stack, and along the upper surfaces of the STI regions; treating the liner layer with a plasma process; after treating the liner layer, forming a hard mask layer on the liner layer; and removing the hard mask layer and the liner layer from the top surface of the layer stack and the sidewalls of the layer stack. The method further includes: forming a dummy gate structure over the fin structure and the STI protection structure; forming source/drain openings on opposing sides of the dummy gate structure, wherein the source/drain openings expose first portions of the first semiconductor material disposed under the dummy gate structure; replacing the first portions of the first semiconductor material with a sacrificial material; after the replacing, forming source/drain regions in the source/drain openings; and after forming the source/drain regions, removing the sacrificial material and replacing the dummy gate structure with a replacement gate structure. In an embodiment, treating the liner layer comprises treating the liner layer using an isotropic plasma process performed using an oxygen-containing gas source. In an embodiment, treating the liner layer comprises treating the liner layer using an anisotropic plasma process performed using a nitrogen-containing gas source.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that protrudes above a substrate, wherein the fin structure comprises a fin and a layer stack over the fin, wherein the layer stack comprises alternating layers of a first semiconductor material and a second semiconductor material;
forming shallow trench isolation (STI) regions on opposing sides of the fin structure;
forming an STI protection structure on upper surfaces of the STI regions, comprising:
forming a liner layer along a top surface of the layer stack, along sidewalls of the layer stack, and along the upper surfaces of the STI regions;
forming a hard mask layer on the liner layer, wherein the hard mask layer is formed to have a first portion along the top surface of the layer stack, a second portion along the sidewalls of the layer stack, and a third portion along the upper surfaces of the STI regions, wherein the first portion and the third portion of the hard mask layer have a higher density than the second portion of the hard mask layer;
removing the first portion and the second portion of the hard mask layer; and
after removing the first portion and the second portion of the hard mask layer, removing the liner layer from the top surface of the layer stack and the sidewalls of the layer stack;
after forming the STI protection structure, forming a dummy gate structure over the fin structure and the STI protection structure;
forming source/drain regions over the fin and on opposing sides of the dummy gate structure; and
after forming the source/drain regions, replacing the dummy gate structure with a replacement gate structure.

2. The method of claim 1, wherein forming the source/drain regions comprises:
forming source/drain openings in the fin structure on the opposing sides of the dummy gate structure, wherein the source/drain openings expose the first semiconductor material and the second semiconductor material; and
forming the source/drain regions in the source/drain openings.

3. The method of claim 2, further comprising, after forming the source/drain openings and before forming the source/drain regions, replacing the first semiconductor material disposed under the dummy gate structure with a sacrificial material.

4. The method of claim 3, wherein replacing the dummy gate structure comprises:
removing the dummy gate structure to expose the sacrificial material and a first portion of the second semiconductor material;
removing the exposed sacrificial material, wherein after removing the exposed sacrificial material, the first portion of the second semiconductor material remains to form channel regions of the semiconductor device; and
forming a gate dielectric material and a gate electrode material around the channel regions.

5. The method of claim 1, wherein forming the hard mask layer comprises performing a plurality of deposition cycles, wherein each deposition cycle of the plurality of deposition cycles is performed by:
depositing a first layer of material on the liner layer; and
treating the first layer of material using an anisotropic plasma process, wherein the anisotropic plasma process turns the first layer of material into a second layer of material, wherein the second layer of material and the first layer of material have different material compositions.

6. The method of claim 5, wherein the first layer of material comprises silicon, the anisotropic plasma process is performed using a gas source comprising nitrogen.

7. The method of claim 1, wherein after removing the liner layer, a remaining portion of the liner layer along the upper surfaces of the STI regions and the third portion of the hard mask layer form the STI protection structure.

8. The method of claim 7, wherein the STI protection structure has a convex upper surface distal from the substrate.

9. The method of claim 1, wherein forming the STI protection structure further comprises, after removing the first portion and the second portion of the hard mask layer and before removing the liner layer:
forming another hard mask layer along the top surface of the layer stack, along the sidewalls of the layer stack, along sidewalls of the fin, and along an upper surface of the third portion of the hard mask layer; and
performing an etching process to remove the another hard mask layer from the top surface of the layer stack, the sidewalls of the layer stack, and the upper surface of the third portion of the hard mask layer, wherein after performing the etching process, a remaining portion of the another hard mask layer is disposed laterally between the liner layer and the third portion of the hard mask layer, wherein after removing the liner layer, the remaining portion of the another hard mask layer, the third portion of the hard mask layer, and a remaining portion of the liner layer along the upper surfaces of the STI regions remain to form the STI protection structure.

10. The method of claim 9, wherein the another hard mask layer has a higher density than the hard mask layer, and the STI protection structure has a concave upper surface distal from the substrate.

11. The method of claim 9, wherein the another hard mask layer has a same density as the hard mask layer, and the STI protection structure has a flat upper surface distal from the substrate.

12. A method of forming a semiconductor device, the method comprising:
forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material;
forming an STI protection structure on upper surfaces of the STI regions, comprising:
forming a liner layer along a top surface of the layer stack, along sidewalls of the layer stack, and along the upper surfaces of the STI regions;
forming a hard mask layer on the liner layer, comprising:
forming a first layer of material on the liner layer; and
performing an anisotropic plasma process to treat the first layer of material, wherein the anisotropic plasma process turns the first layer of material into a second layer of material having a different material composition from the first layer of material;
removing the hard mask layer from the top surface of the layer stack and the sidewalls of the layer stack; and
after removing the hard mask layer, removing the liner layer from the top surface of the layer stack and the sidewalls of the layer stack, wherein after removing the liner layer, a remaining portion of the liner layer and a remaining portion of the hard mask layer cover the upper surfaces of the STI regions;
forming a dummy gate structure over the fin structure and the STI protection structure;
forming source/drain regions on opposing sides of the dummy gate structure; and
after forming the source/drain regions, replacing the dummy gate structure with a replacement gate structure.

13. The method of claim 12, wherein the hard mask layer is formed to include a first portion along the top surface of the layer stack, a second portion along the sidewalls of the layer stack, and a third portion along the upper surfaces of the STI regions, wherein the first portion and the third portion of the hard mask layer have a higher density than the second portion of the hard mask layer.

14. The method of claim 12, wherein forming the STI protection structure further comprises, after removing the hard mask layer and before removing the liner layer:
forming another hard mask layer along the top surface of the layer stack, along the sidewalls of the layer stack, along sidewalls of the fin, and along an upper surface of the remaining portion of the hard mask layer; and
performing an etching process to remove the another hard mask layer from the top surface of the layer stack, the sidewalls of the layer stack, and the upper surface of the remaining portion of the hard mask layer, wherein after performing the etching process, a remaining portion of the another hard mask layer is disposed laterally between the liner layer and the remaining portion of the hard mask layer.

15. The method of claim 14, wherein after removing the liner layer, the remaining portion of the liner layer extend along the sidewalls of the fin and along the upper surfaces of the STI regions, wherein the remaining portion of the another hard mask layer, the remaining portion of the hard mask layer, and the remaining portion of the liner layer form the STI protection structure.

16. The method of claim 12, wherein forming the source/drain regions comprises:
forming source/drain openings in the fin structure on the opposing sides of the dummy gate structure;
after forming the source/drain openings, replacing the first semiconductor material disposed under the dummy gate structure with a sacrificial material; and
after the replacing, forming the source/drain regions in the source/drain openings.

17. The method of claim 16, wherein replacing the dummy gate structure comprises:
forming an interlayer dielectric (ILD) layer over the source/drain regions around the dummy gate structure;
removing the dummy gate structure to form a gate trench in the ILD layer, wherein the gate trench exposes the sacrificial material and a first portion of the second semiconductor material;
selectively removing the exposed sacrificial material, wherein after the selectively removing, the first portion of the second semiconductor material remain to form nanostructures; and
forming a gate dielectric material and a gate electrode material around the nanostructures.

18. A method of forming a semiconductor device, the method comprising:
forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material;
forming an STI protection structure on upper surfaces of the STI regions, comprising:
forming a liner layer along a top surface of the layer stack, along sidewalls of the layer stack, and along the upper surfaces of the STI regions;
treating the liner layer with a plasma process;
after treating the liner layer, forming a hard mask layer on the liner layer; and
removing the hard mask layer and the liner layer from the top surface of the layer stack and the sidewalls of the layer stack;
forming a dummy gate structure over the fin structure and the STI protection structure;
forming source/drain openings on opposing sides of the dummy gate structure, wherein the source/drain openings expose first portions of the first semiconductor material disposed under the dummy gate structure;
replacing the first portions of the first semiconductor material with a sacrificial material;
after the replacing, forming source/drain regions in the source/drain openings; and
after forming the source/drain regions, removing the sacrificial material and replacing the dummy gate structure with a replacement gate structure.

19. The method of claim 18, wherein treating the liner layer comprises treating the liner layer using an isotropic plasma process performed using an oxygen-containing gas source.

20. The method of claim 18, wherein treating the liner layer comprises treating the liner layer using an anisotropic plasma process performed using a nitrogen-containing gas source.
